(19) United States
(12) Patent Application Publication
(10) Pub. No.: US 2025/0169089 A1
(43) Pub. Date: May 22, 2025

(54) METHOD FOR MANUFACTURING SEMICONDUCTOR DEVICE AND PLASMA PROCESSING METHOD

(71) Applicant: Hitachi High-Tech Corporation, Minato-ku, Tokyo (JP)

(72) Inventors: Makoto MIURA, Tokyo (JP); Kiyohiko SATO, Tokyo (JP); Kohei KAWAMURA, Tokyo (JP); Satoshi SAKAI, Tokyo (JP)

(21) Appl. No.: 18/279,809

(22) PCT Filed: Aug. 9, 2022
(86) PCT No.: PCT/JP2022/030488

§ 371 Date: Aug. 31, 2023

(51) Int. Cl. H10D 30/01; H01L 21/02; H01L 21/311

(52) U.S. Cl. CPC H10D 30/0196; H01L 21/0228; H01L 21/31116

(57) ABSTRACT

A method of manufacturing step of a device having a gate and a silicon substrate that are insulation-isolated from each other. In the method, germanium compositions of a silicon germanium sacrificial layer for forming a stacked channel and a germanium composition of a silicon germanium sacrificial layer for insulation-isolating the gate and the substrate are not changed. After the stacked film is etched, a protective dielectric film is formed on a sidewall of the stacked film, which is repeated using different protective film materials. Thereafter, a silicon sacrificial layer and a silicon germanium sacrificial layer remaining in a lower portion are removed by isotropic etching to form a region in which the insulating isolation film is embedded. The steps from the formation of the stacked film of the protective dielectric films to the removal of the sacrificial layer by etching in the continuous process use the same apparatus.

### DESCRIPTION

### Technical Field

The present disclosure relates to a method for manufacturing a semiconductor device and a plasma processing method.

### Background Art

Large integration of a transistor is essential for continuously improving a function and performance of an integrated circuit chip. The high integration of the transistor has been mainly achieved by miniaturization or scaling down of the transistor. In order to achieve the scaling of the transistor while maintaining or improving performance of the transistor, many improvements have been made in a transistor structure and a material constituting the transistor. Examples of the improvement include introduction of a strain into a source region and a drain region, introduction of a gate dielectric film with high dielectric constant and a metal, and introduction of a structure change such as a change from planar type to fin type in a metal oxide semiconductor field effect transistor (MOSFET).

A fin type FET has a structure in which gate controllability can be improved and a short channel effect (that is, an increase in leakage current) due to a reduction of a gate length accompanying the scaling of the transistor can be suppressed by covering a periphery of a fin type channel having a three-dimensional structure with the gate, Furthermore, as the scaling proceeds, a gate all around (GAA) type FET in which a channel is a wire-shaped (thin wire) or sheet-shaped stacked body and a periphery of the channel is covered with a gate is expected. In the GAA type FET, by covering an entire periphery of the wire-shaped or Sheet-shaped channel (a nanowire channel or nanosheet channel) with the gate, the gate controllability can be further improved and the short channel effect can be further suppressed as compared with the fin type FET,

However, in the GAA type FET, since the gate covering the channel is also in contact with a semiconductor substrate, the FET is formed simultaneously on a semiconductor substrate side. The FET formed on the semiconductor substrate side has a planar type structure whose gate controllability is weaker than that of the GAA type, and thus degradation of transistor characteristics is caused.

NPL 1 refers to a problem of deterioration of transistor characteristics due to the planar type FET, that is, a parasitic FET formed on the semiconductor substrate side, and points out the necessity of providing an insulating film immediately below a gate to electrically isolate the gate from the semiconductor substrate.

PTL 1 discloses a specific process for forming an insulating isolation film between the gate and the semiconductor substrate. That is, a second SiGe sacrificial layer having a germanium (Ge) composition larger than that of a silicon germanium (SiGe) sacrificial layer is formed under a stacked structure including a silicon (Si) channel and the SiGe sacrificial layer for forming nanowire channels or nanosheet channels. In the stacked structure in which a sidewall is exposed during the process, only the second SiGe sacrificial layer is selectively removed by etching, and the removed region is filled with the insulating film. Accordingly, the nanowire channel or the nanosheet channel can be electrically isolated from the silicon substrate.

PTL 2 discloses a process for covering, with a protective film, a sidewall of a Si/SiGe stacked film for forming a nanowire channel or a nanosheet channel, exposing only a sidewall of a second SiGe sacrificial layer that is present in a lower portion of the SiGe/Si stacked structure, removing the second SiGe sacrificial layer, and filling the removed region with an insulating film. Since the SiGe sacrificial layers in the SiGe/Si stacked film are covered with the protective film at the time of etching the second SiGe sacrificial layer, it is not necessary to make the Ge composition of the second SiGe sacrificial layer larger than the Ge composition of the SiGe sacrificial layers in the SiGe/Si stacked film, and concern about strain relaxation or the like due to introduction of the SiGe layer having a large Ge composition is reduced.

### CITATION LIST

### Patent Literature

PTL 1: US2019/0393351

PTL 2: US2020/0105756

### Non Patent Literature

NPL 1: J. Zhang, et al., “Full Bottom Dielectric Isolation to Enable Stacked Nanosheet Transistor for Low Power and High Performance Applications”. Proceedings of IEDM 2019, 2019, pp. 250 to 253

### SUMMARY OF INVENTION

### Technical Problem

In the case of forming the insulating isolation film between the gate and the semiconductor substrate disclosed in PTL 1, it is necessary to make the Ge composition of the second SiGe sacrificial layer formed under the Si/SiGe stacked film for forming the nanowire channels or the nanosheet channels larger than a Ge composition of a first SiGe sacrificial layers in an upper Si/SiGe stacked film to provide etching selectivity. Generally, the Ge composition of the first SiGe sacrificial layers in the upper Si/SiGe stacked film is set to 15% to 25%, and the Ge composition of the second SiGe sacrificial layer is set to 40% to 50%. In this case, an amount of strain due to a difference in lattice constant between Si and SiGe increases in the second SiGe sacrificial layer, and there is concern that a defect due to the strain relaxation is likely to occur. In a SiGe layer having a Ge composition of 50%, a critical film thickness at which the strain relaxation occurs is about 20 nm or less at a standard epitaxial growth temperature (550° C. to 600° C.) for forming the SiGe layer. Considering the strain and the like at the time of forming the upper Si/SiGe stacked film, it is estimated that a film thickness of the second SiGe sacrificial layer needs to be designed to be extremely thin, for example, about 10 nm or less. The film thickness is extremely thin from the viewpoint of ensuring a sufficient process margin and effectively isolating the gate electrically from the semiconductor substrate. The second SiGe sacrificial layer is removed after the second SiGe sacrificial layer and the upper Si/SiGe stacked film are etched in a vertical direction along a pattern including a gate and a gate spacer formed above the second SiGe sacrificial layer and the upper Si/SiGe stacked film. That is, when the second SiGe sacrificial layer is removed by etching, a sidewall of the first SiGe sacrificial layers in the upper Si/SiGe stacked film is also exposed, and thus an upper first SiGe sacrificial layer are also exposed to etching at the time of etching the second SiGe sacrificial layer. Since the two types of films have different Ge compositions but are the same SiGe layer, it is difficult to provide complete etching selectivity, and when the second SiGe sacrificial layer is etched, the first SiGe sacrificial layers in the upper Si/SiGe stacked film are also inevitably etched by a certain amount. For this reason, there are concerns that the subsequent processes are influenced by the first SiGe sacrificial layer etching and a defect such as an increase in transistor leakage current occurs.

On the other hand, in the process of the GAA type FET disclosed in PTL 2, a method for depositing a dielectric film on the sidewall after the Si/SiGe stacked film and a lower second SiGe layer sacrificial are etched perpendicularly along the pattern, protecting only the upper Si/SiGe stacked film portion with the dielectric film, only exposing the second SiGe sacrificial layer, and removing only the second SiGe sacrificial layer is adopted. Since the first SiGe sacrificial layers of the upper Si/SiGe stacked film are protected by the dielectric film at the time of etching the second SiGe sacrificial layer, the problem of etching selectivity concerned in PTL 1 is resolved. Since it is also possible to make the Ge composition of the second SiGe sacrificial layer equal to that of the first SiGe sacrificial layers in the upper Si/SiGe stacked film, there is less concern about the strain relaxation. For this reason, the film thickness of the second SiGe sacrificial layer can be set to be large, and a sufficient process margin can be ensured, and concern about transistor failure due to the strain relaxation is reduced. However, in the GAA type FET process disclosed in PTL 2, there is concern that the number of processes may be greatly increased as compared with the process disclosed in PTL 1. In PTL 2, a method for protecting only the upper Si/SiGe stacked film portion with the dielectric film and exposing only the second SiGe sacrificial layer is performed by the following process. First, the Si/SiGe stacked film and the lower second SiGe sacrificial layer are etched in the vertical direction along the pattern, and then a dielectric film having a constant film thickness is conformally deposited to protect the etched sidewall. Thereafter, a trench formed by the pattern is filled with a coating film such as a spin-on carbon film, and the carbon film is etched by a certain amount in the vertical direction. Here, an etching amount is adjusted such that an upper end of the etched carbon film is located between an upper end and a lower end of the second SiGe sacrificial layer. Next, a film of titanium nitride (TiN) or the like is deposited on the carbon film, the trench formed by the pattern is filled again, and an underlying carbon film is removed. When the dielectric film exposed at this time is removed by etching in a horizontal direction, the sidewall of the second SiGe sacrificial layer is exposed. Thereafter, the second SiGe sacrificial layer is selectively removed by etching. Finally, the TiN film and the dielectric film are removed by etching to obtain a structure in which only the second SiGe sacrificial layer is removed. In the above process, nine steps such as film formation and etching are added to the process disclosed in PTL 1, resulting in a large increase in the number of process steps. When the carbon film is etched by a certain amount in the vertical direction, since there is no technique for directly evaluating a relative position between the SiGe sacrificial layer and the upper end of the carbon film, it is difficult to adjust the etching amount such that the upper end of the etched carbon film is located between the upper end and the lower end of the second SiGe sacrificial layer whose sidewall is covered with the dielectric film.

The present disclosure provides a plasma processing method in which, in a manufacturing step of a GAA type FET in which gate and a semiconductor substrate are electrically isolated from each other, after a Si/SiGe stacked film and a second SiGe sacrificial layer formed under the Si/SiGe stacked film are patterned, a step of protecting a sidewall of the Si/SiGe stacked film with a stacked dielectric film, and removing only the second SiGe sacrificial layer by etching, and a process from the patterning to the removal of the second SiGe sacrificial layer can be performed continuously by the same apparatus.

### Solution to Problem

Outlines of representative embodiments in the present disclosure will be briefly described as follows.

According to an aspect of the present disclosure, a method for manufacturing a semiconductor device or a plasma processing method includes:

a first step of depositing a protective dielectric film on a sidewall of a semiconductor stacked film in which a part of the semiconductor stacked film is etched vertically;

a second step of subjecting the protective insulating film to anisotropic etching in a vertical direction to expose a surface of the semiconductor stacked film;

a third step of repeating the first step and the second step a plurality of times using a material of a dielectric film different from that of the protective dielectric film, and forming, on the sidewall, a stacked protective dielectric film; and

a fourth step of removing the semiconductor stacked film present in a lower portion of the protective dielectric film by isotropic etching.

### Advantageous Effects of Invention

According to the aspect of the present disclosure, in a manufacturing step of a three-dimensional structure device such as a GAA type FET, in a process for electrically isolating a gate and a silicon substrate and preventing formation of a planar parasitic FET formed on a silicon substrate side, it is possible to prevent the occurrence of a defect, and to significantly prevent an increase in the number of process steps due to device characteristics by which a continuous process in which a plurality of steps are performed in the same apparatus can be performed.

Other technical problems and novel characteristics will be apparent from a description of this description and the accompanying drawings.

### BRIEF DESCRIPTION OF DRAWINGS

FIG. 1A is a bird's-eye view showing a manufacturing step of a GAA type FET in which gates and a semiconductor substrate according to Embodiment 1 are electrically isolated from each other.

FIG. 1B is a bird's-eye view showing a manufacturing step of the GAA type FET in which the gates and the semiconductor substrate according to Embodiment 1 are electrically isolated from each other.

FIG. 10 is a bird's-eye view showing a manufacturing step of the GAA type FET in which the gates and the semiconductor substrate according to Embodiment 1 are electrically isolated from each other.

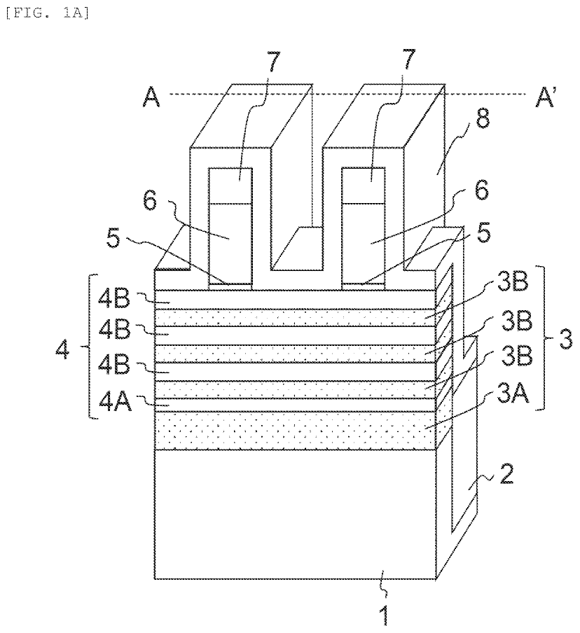

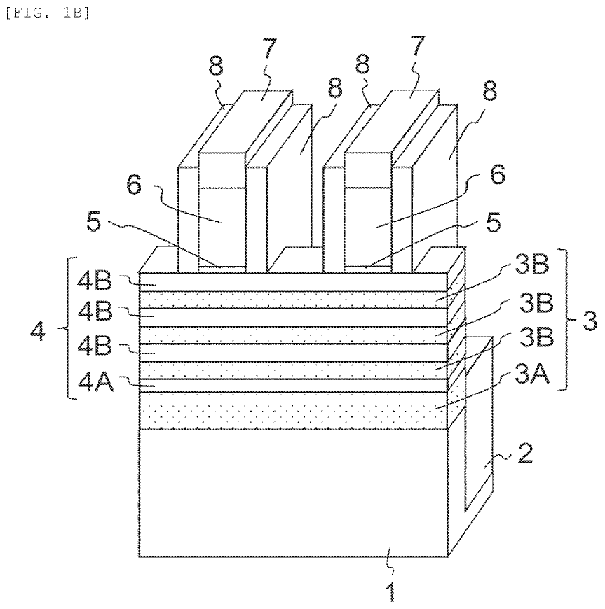

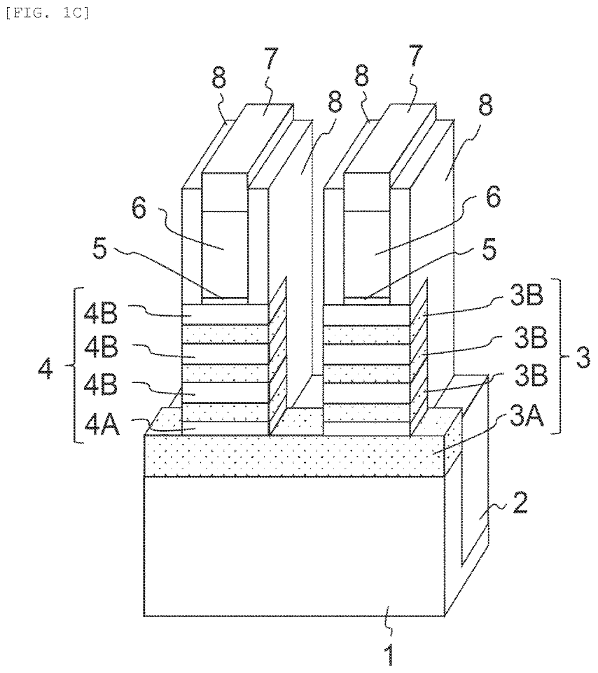

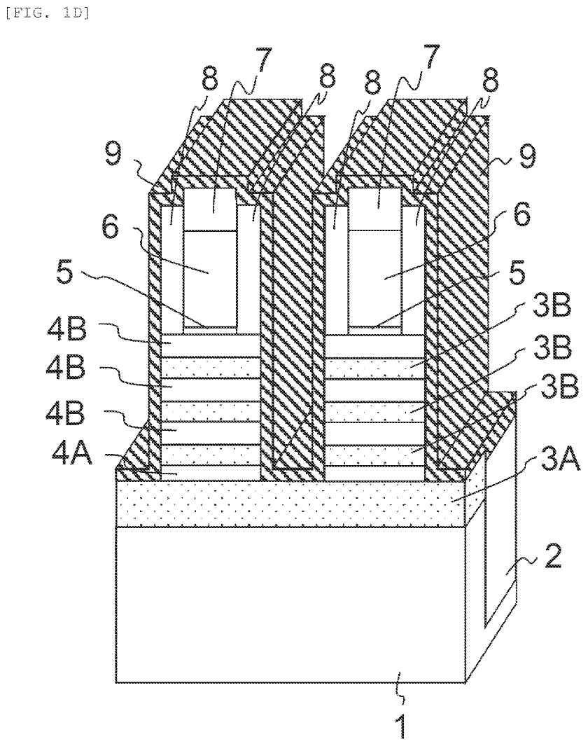

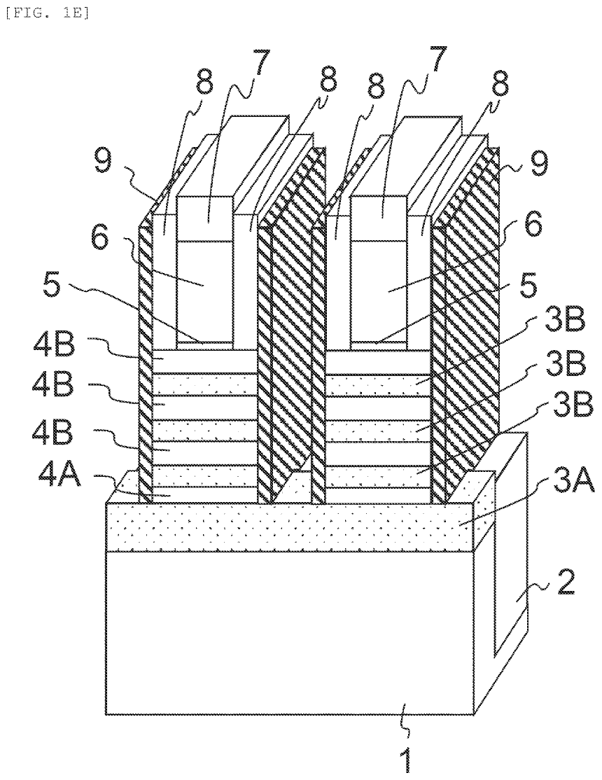

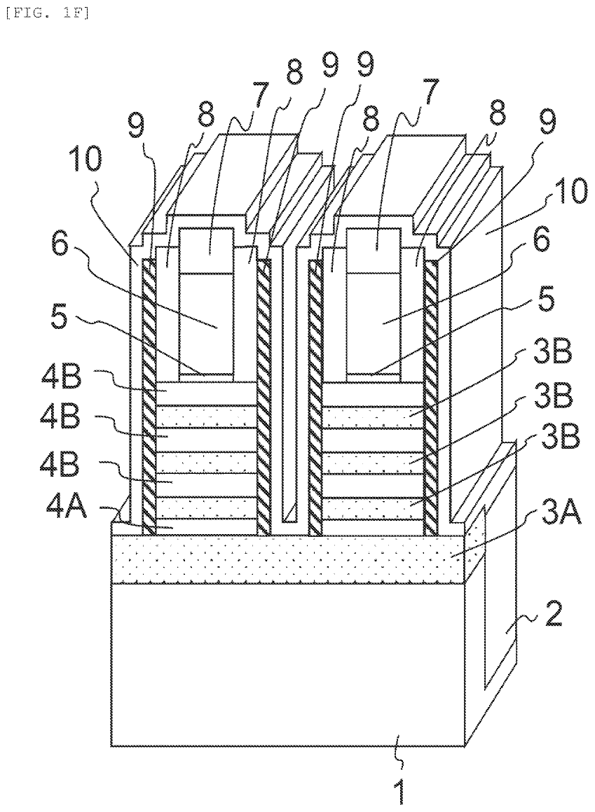

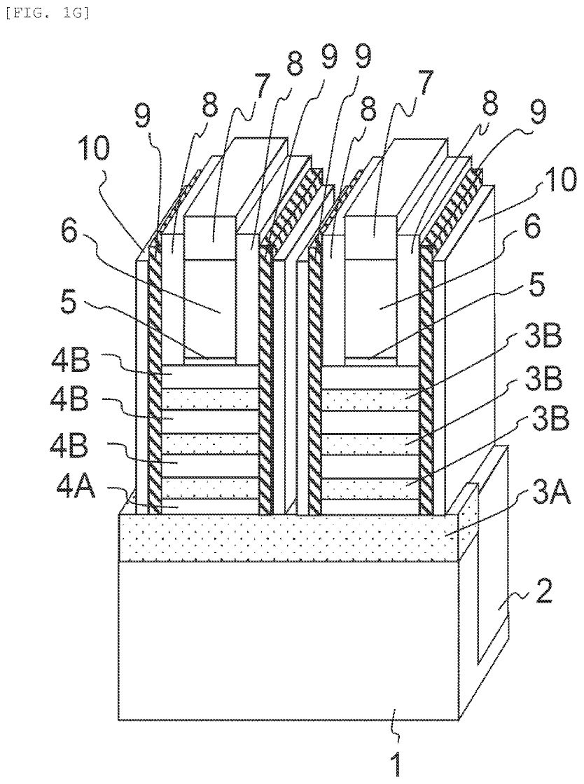

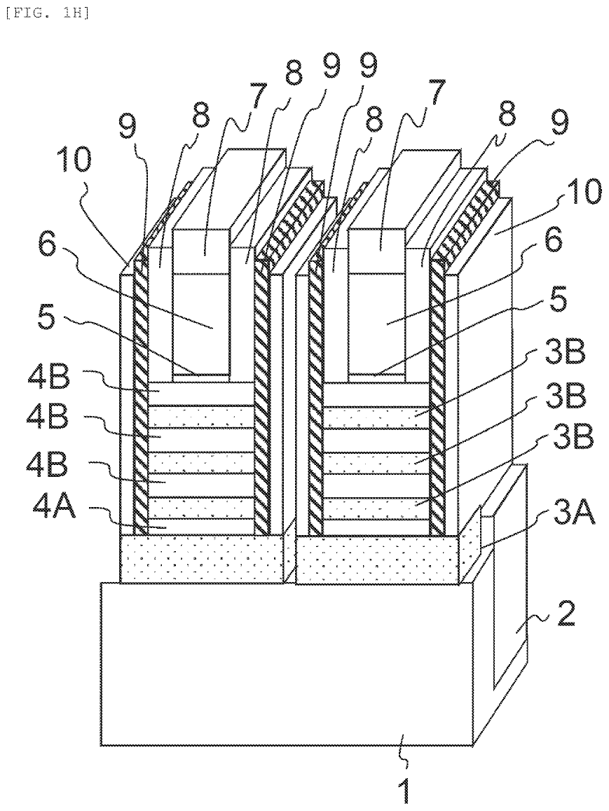

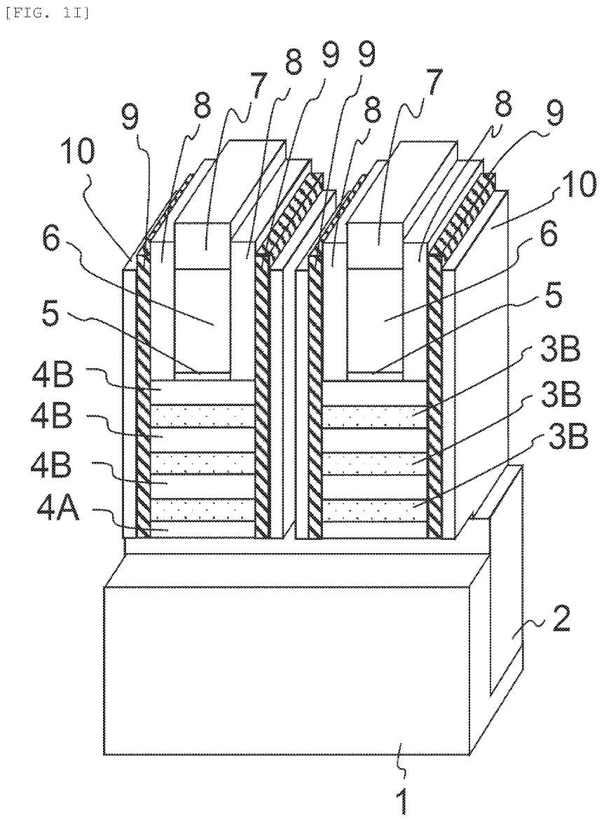

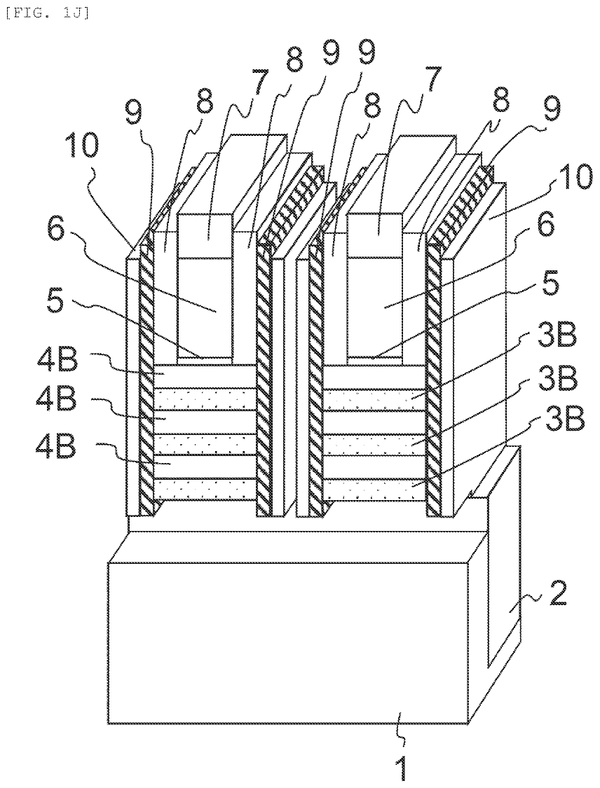

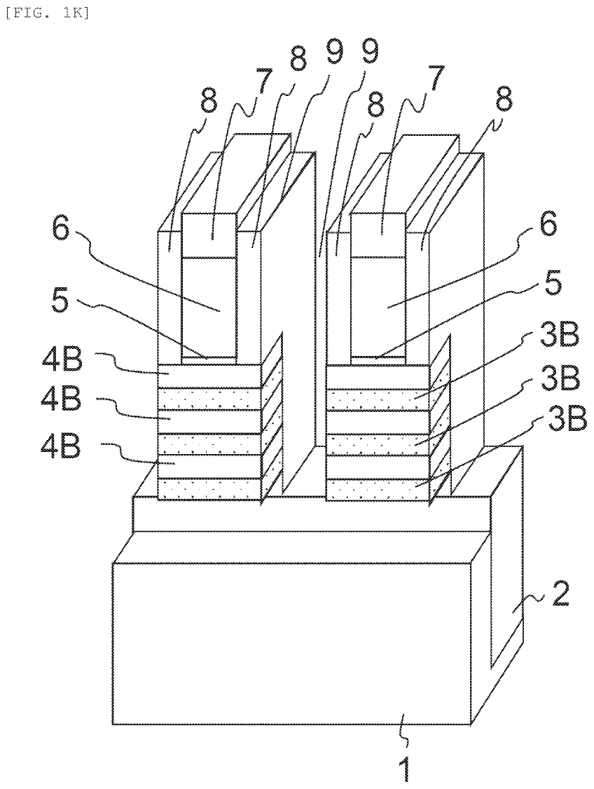

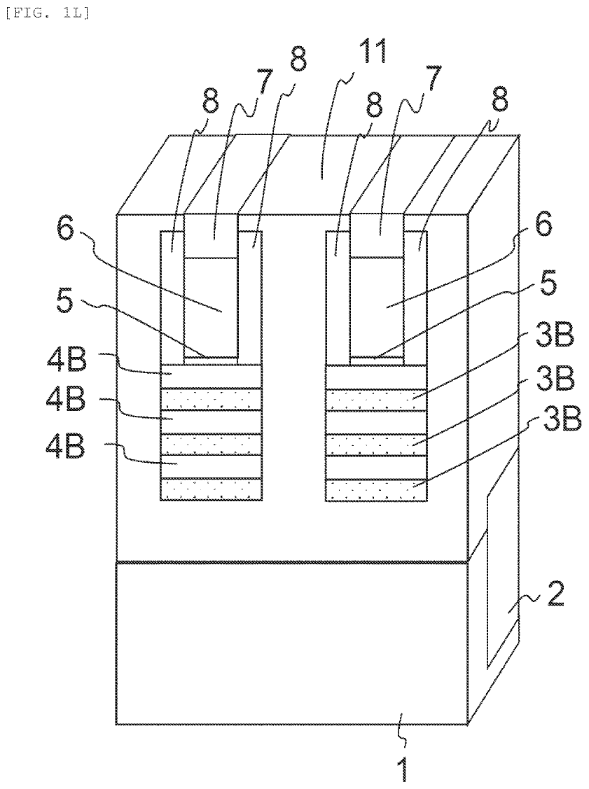

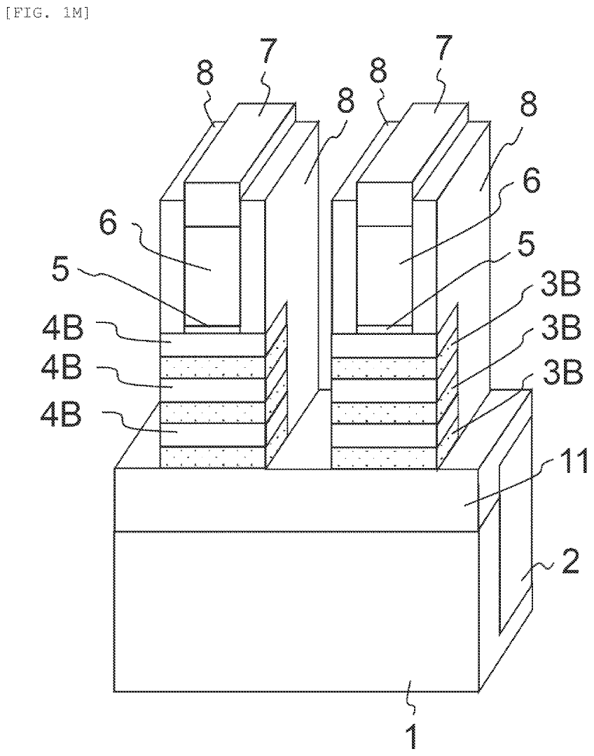

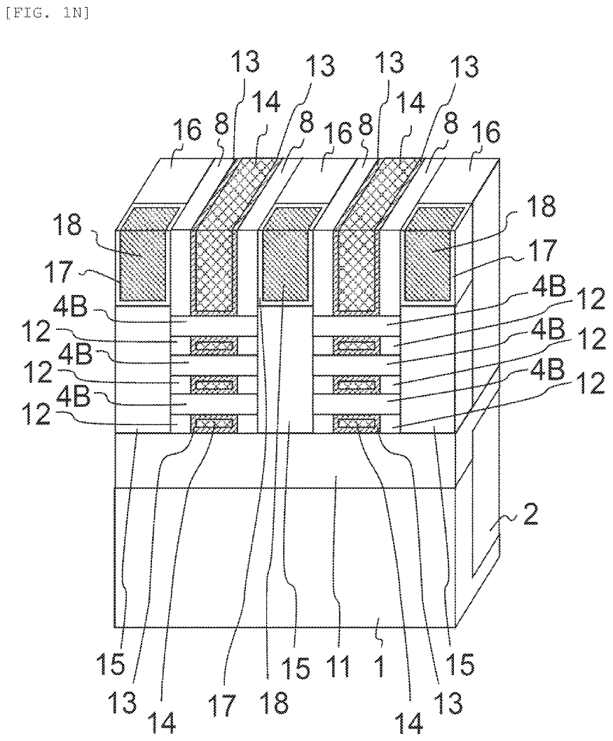

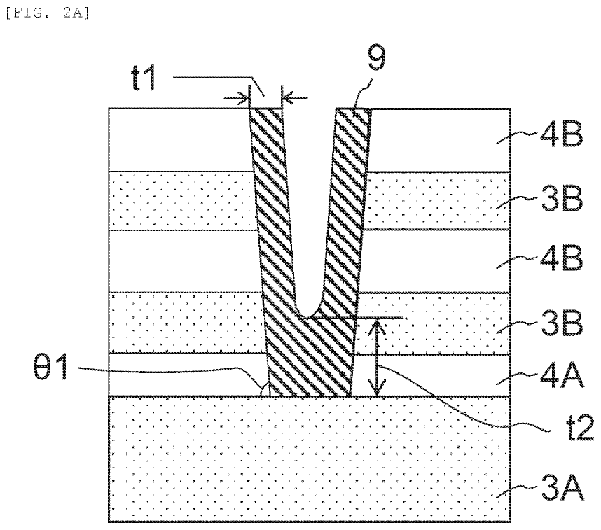

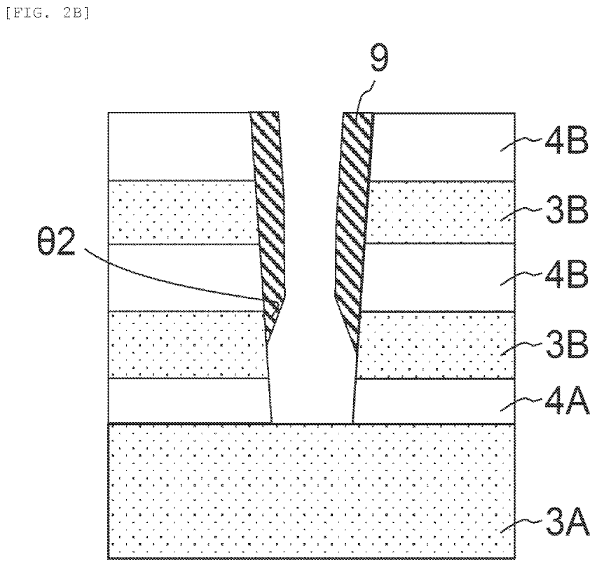

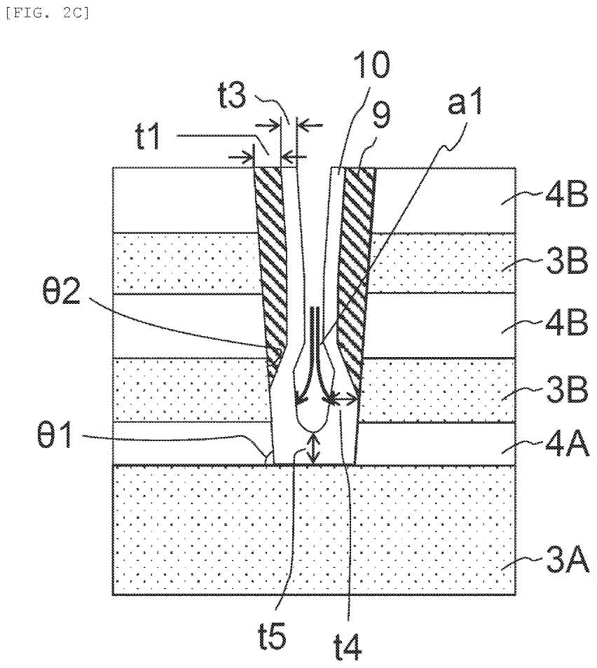

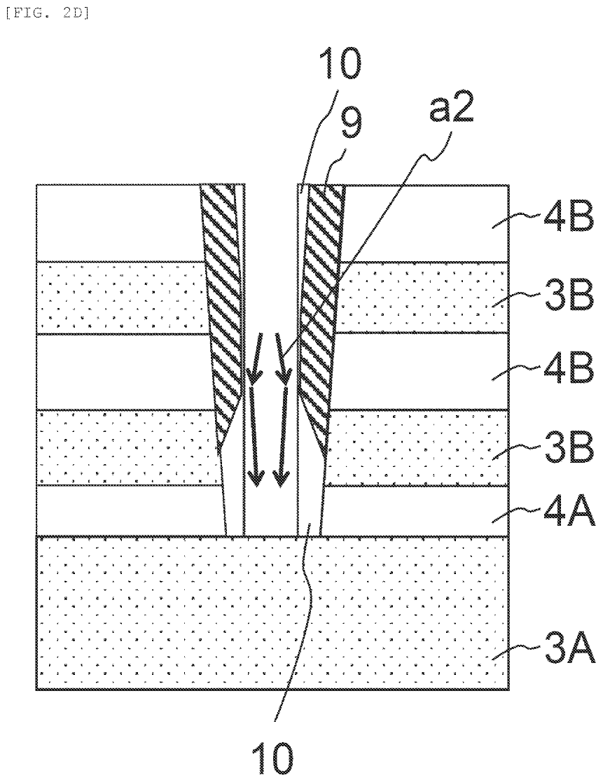

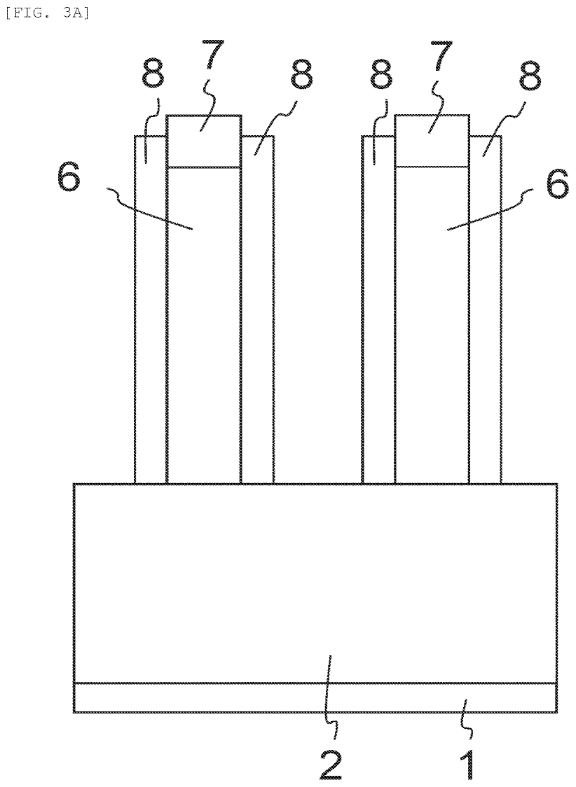

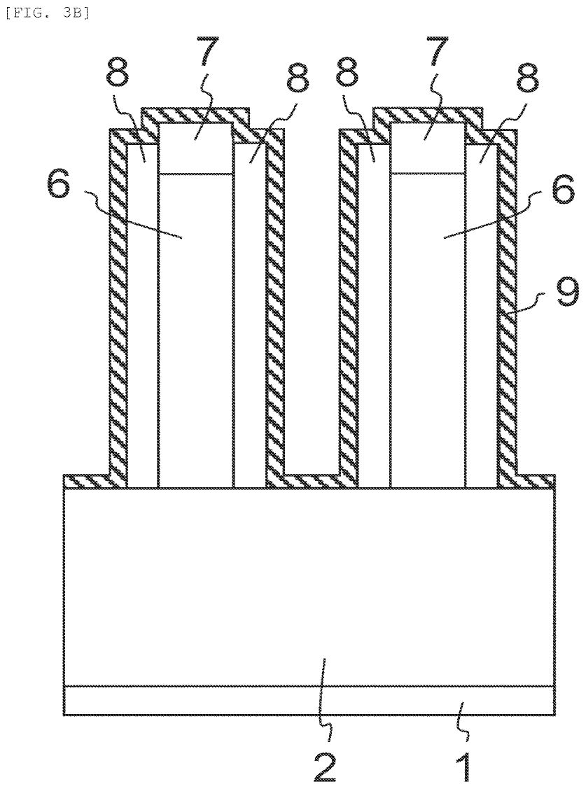

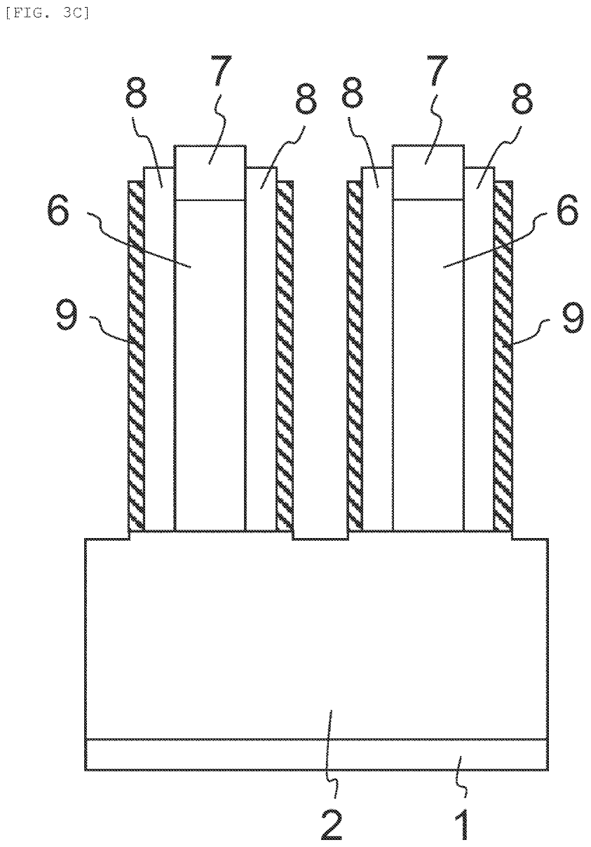

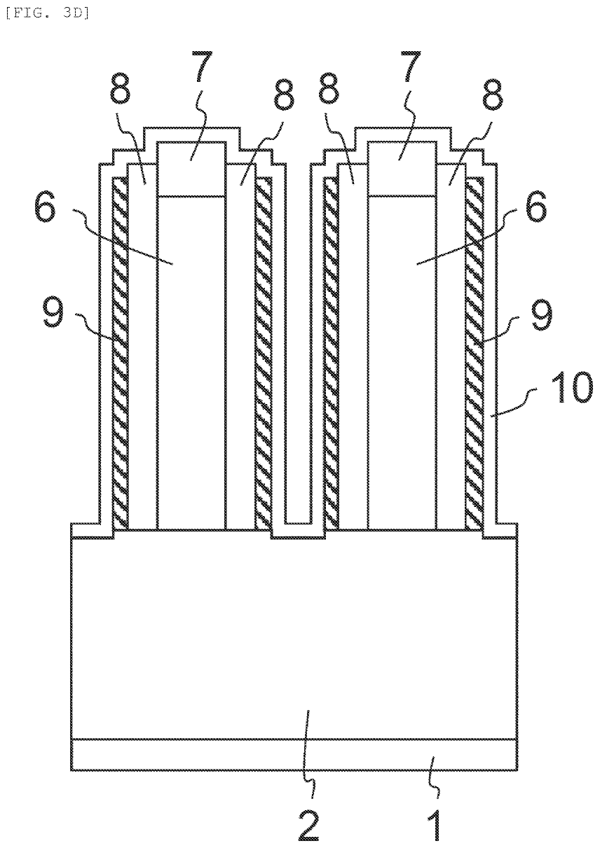

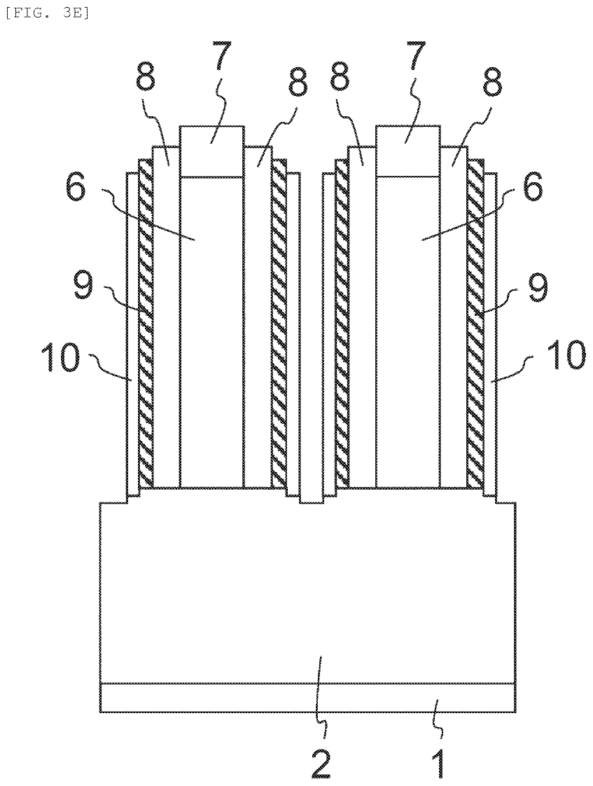

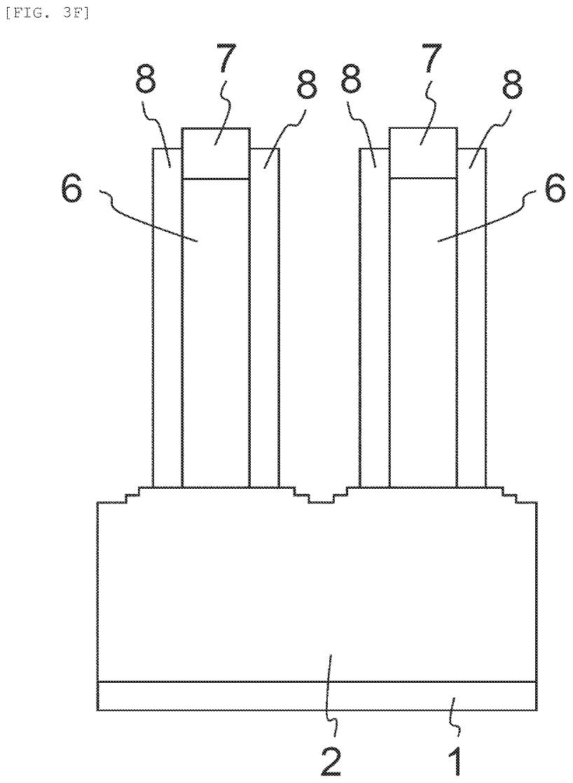

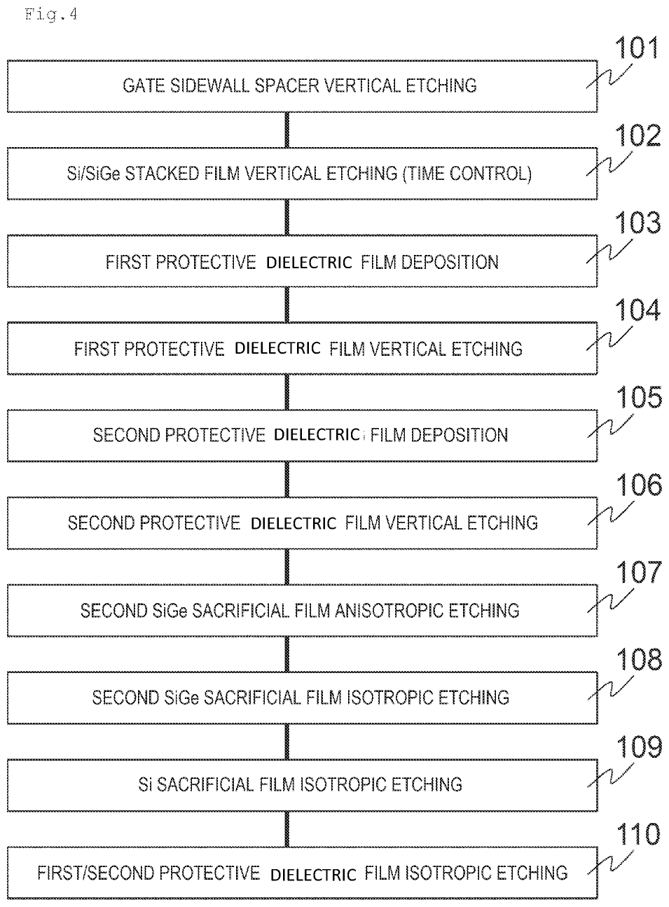

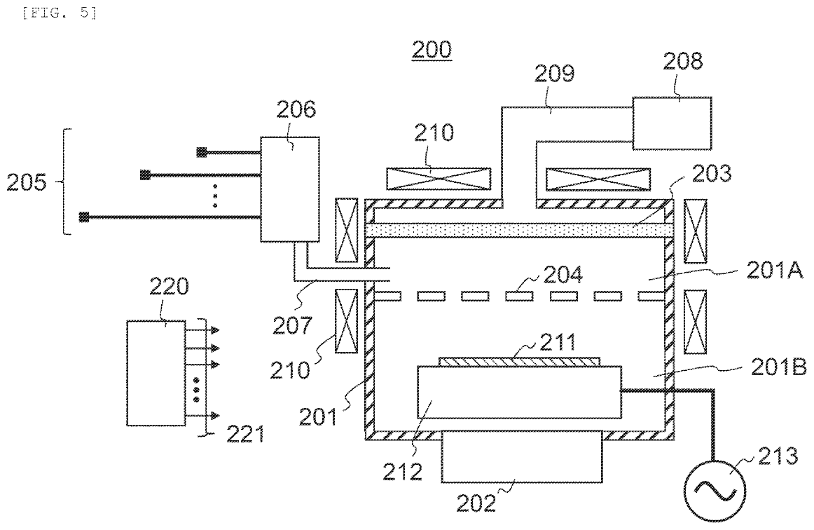

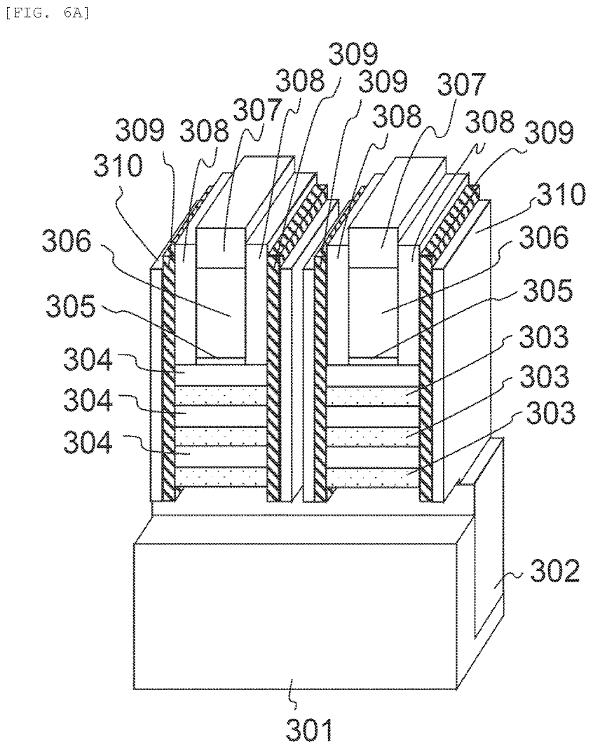

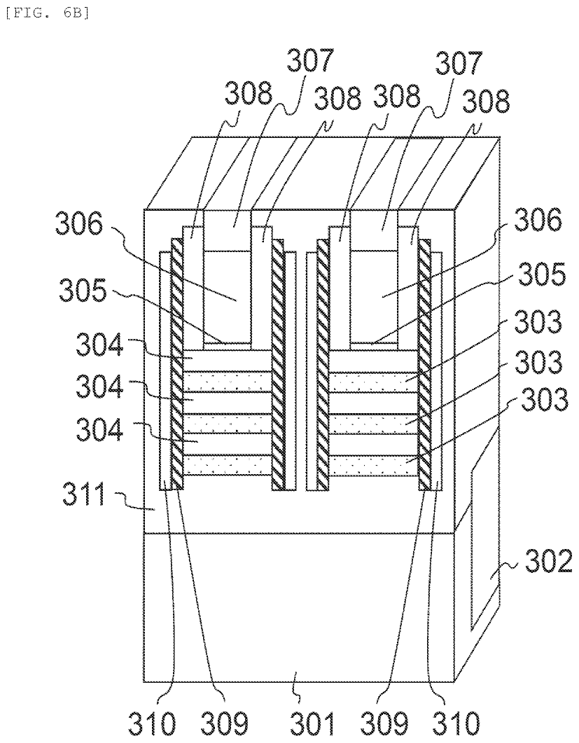

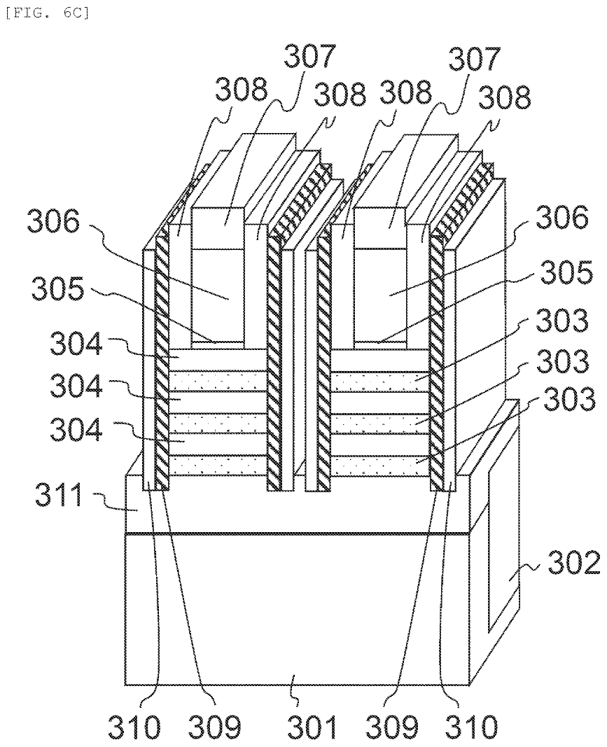

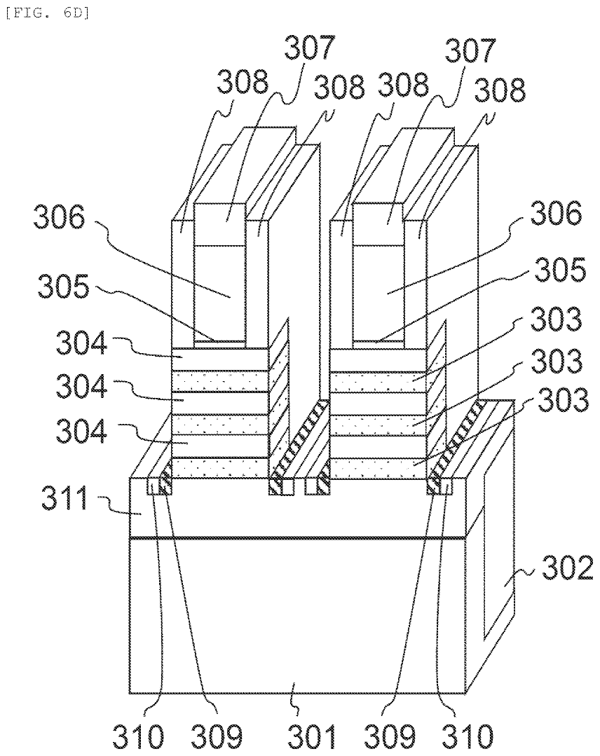

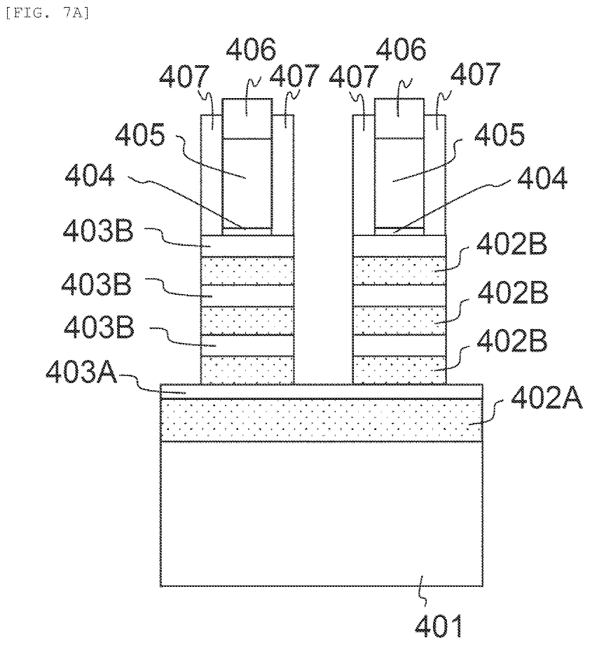

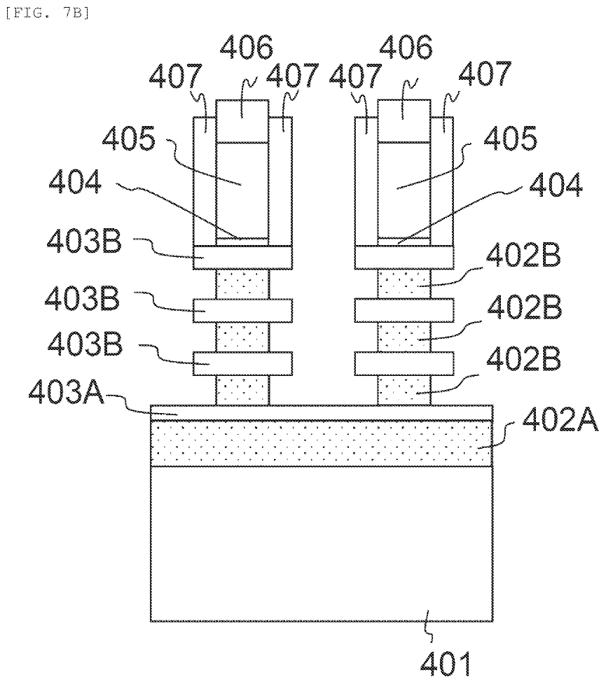

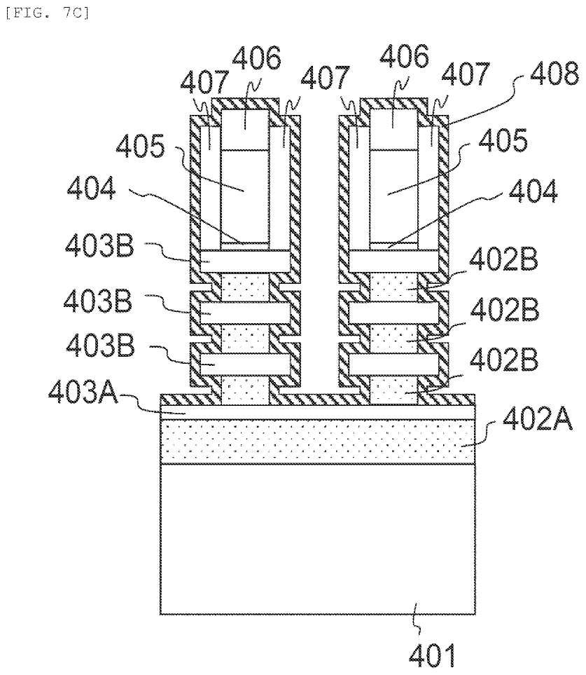

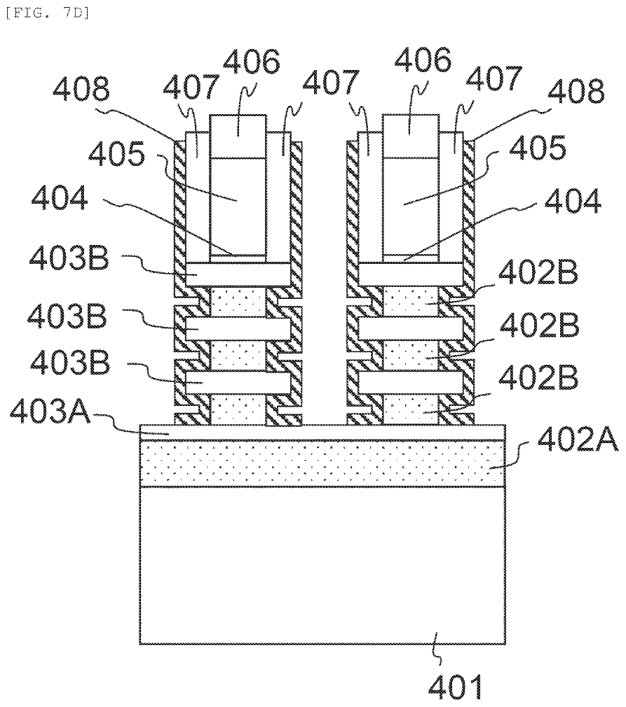

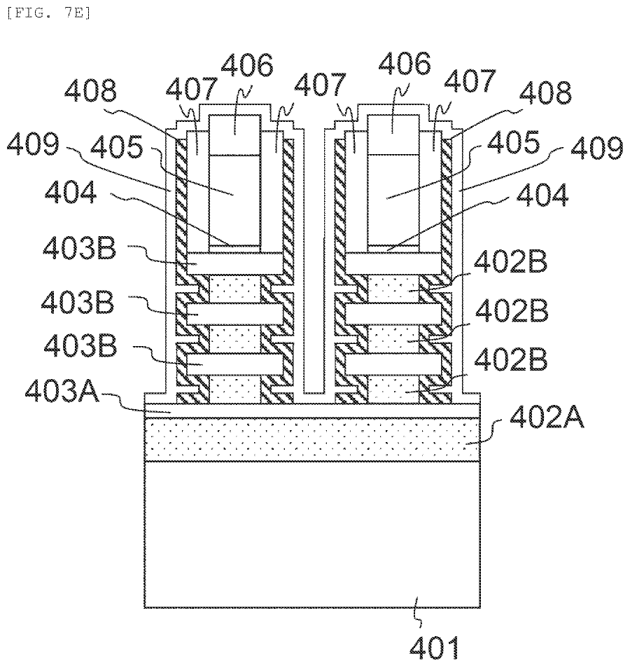

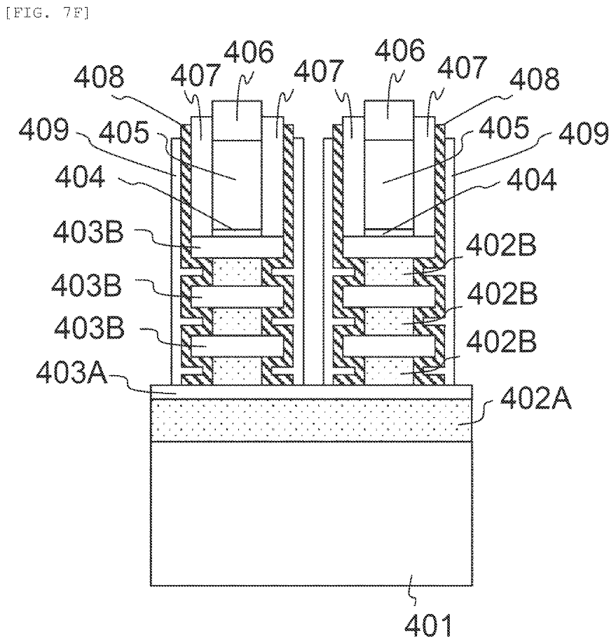

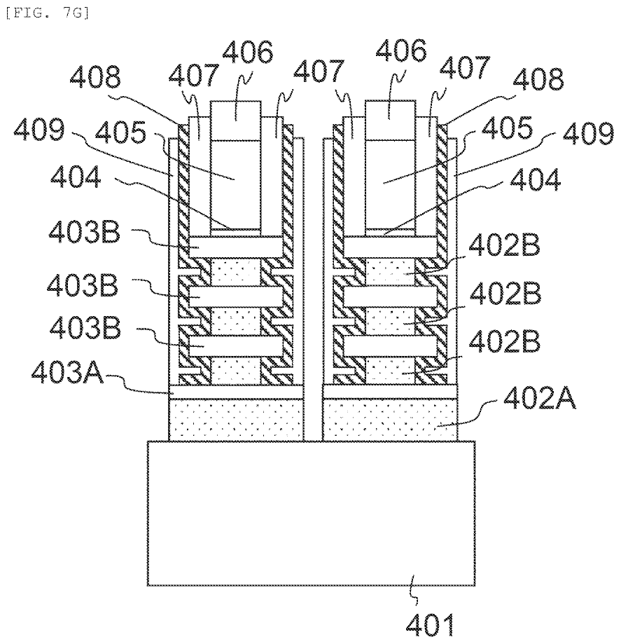

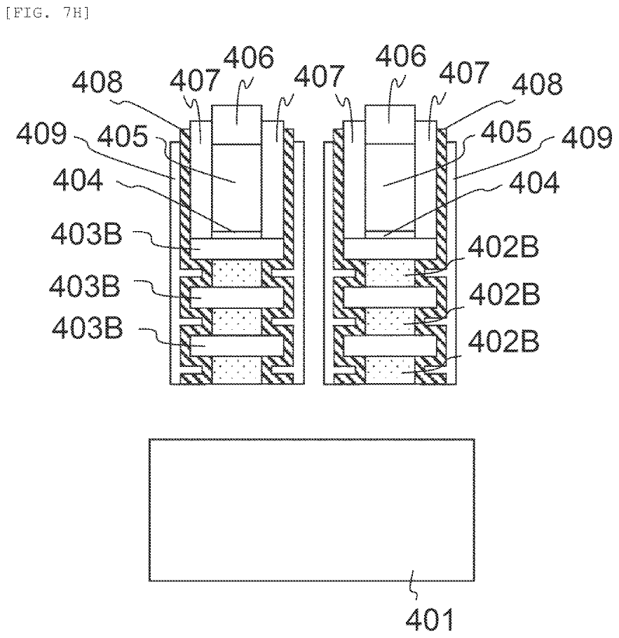

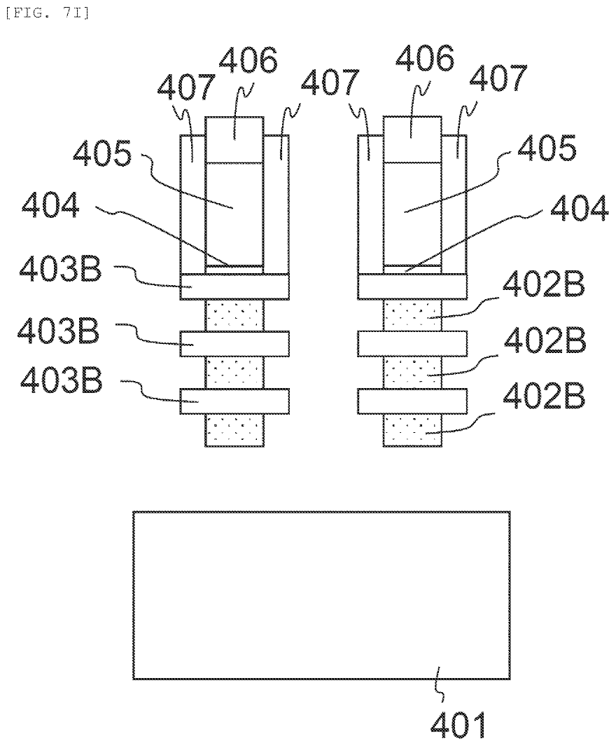

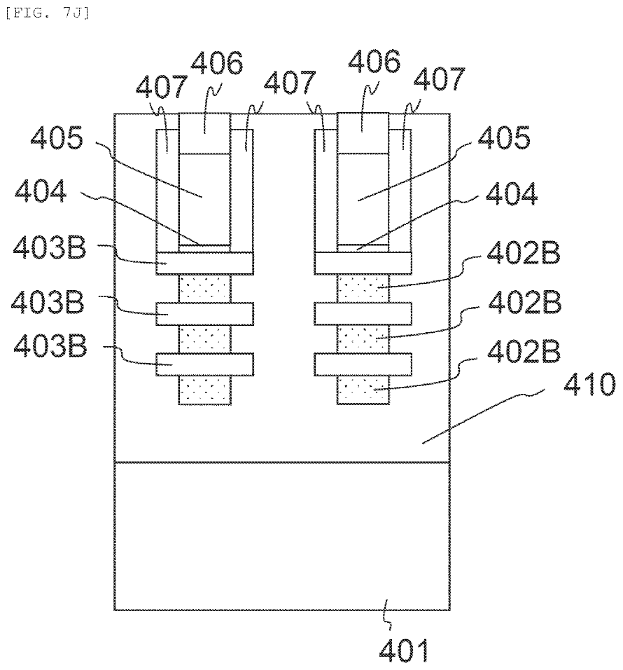

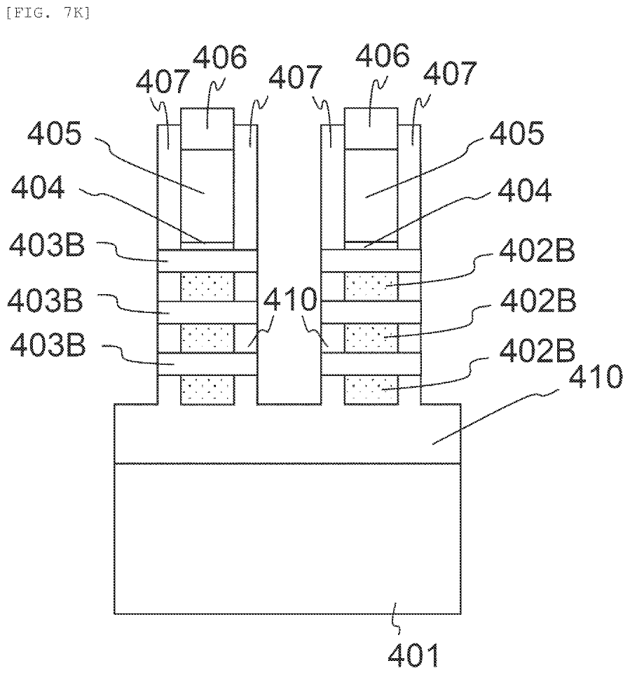

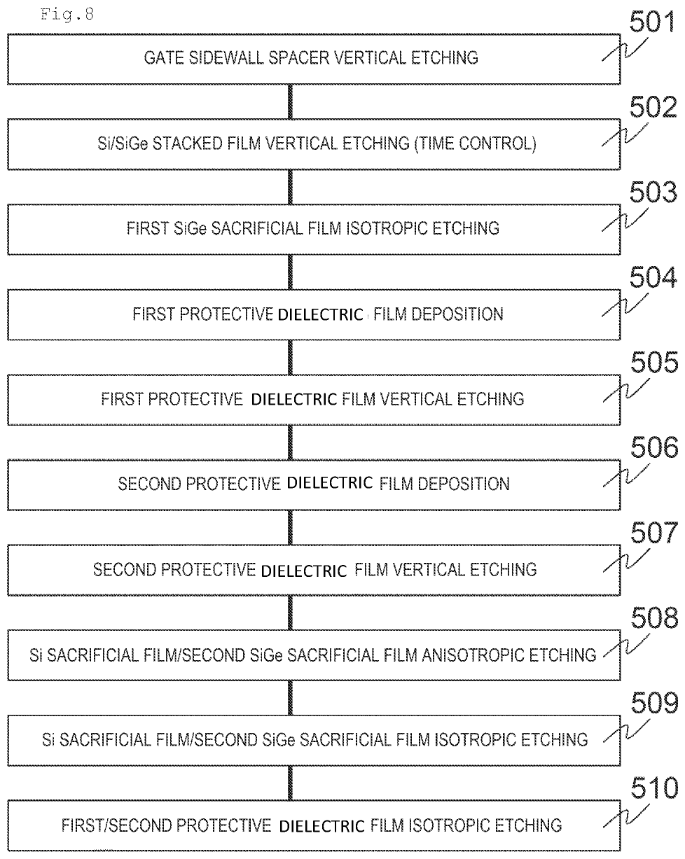

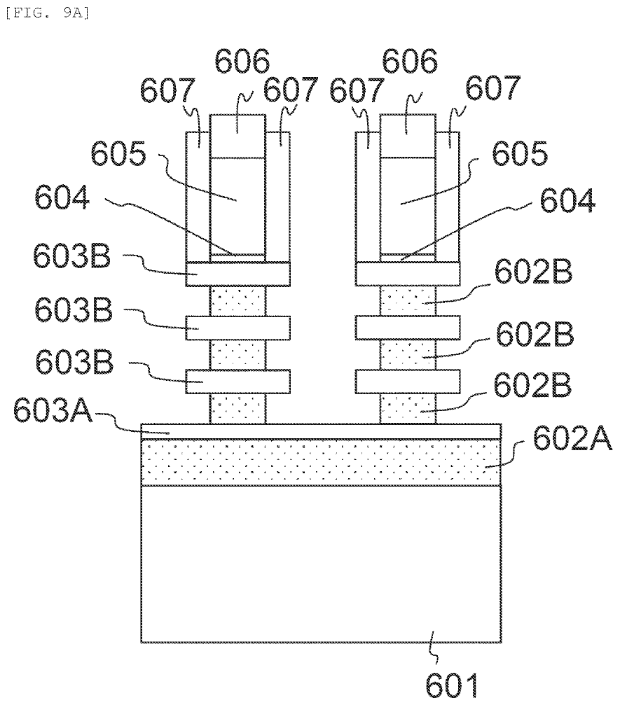

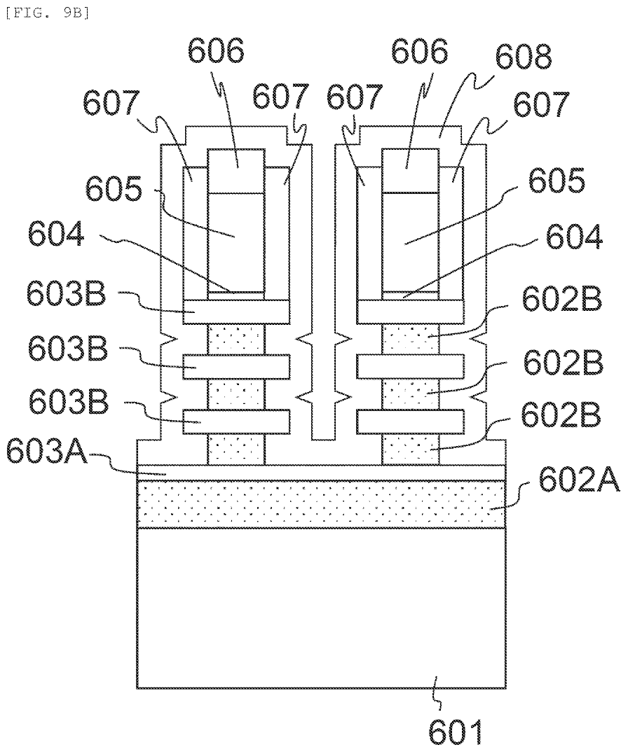

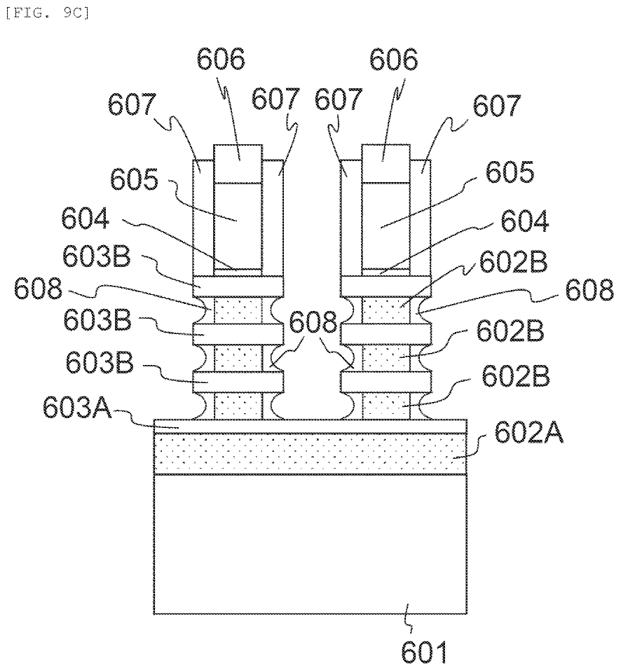

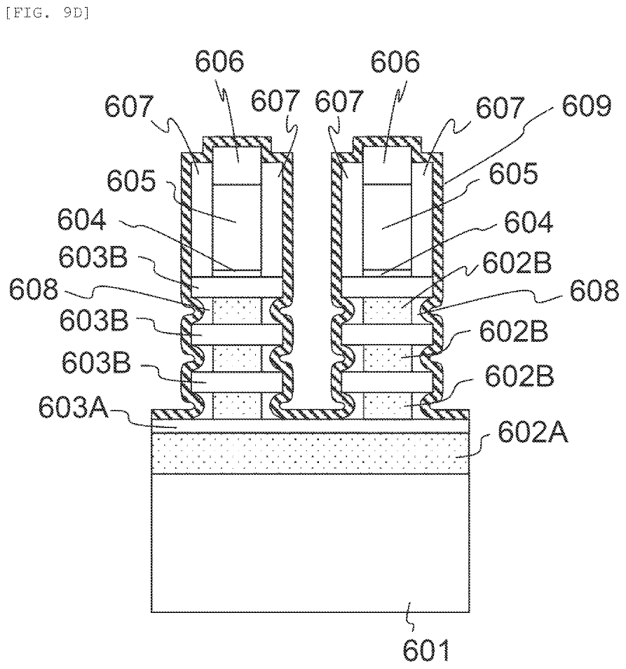

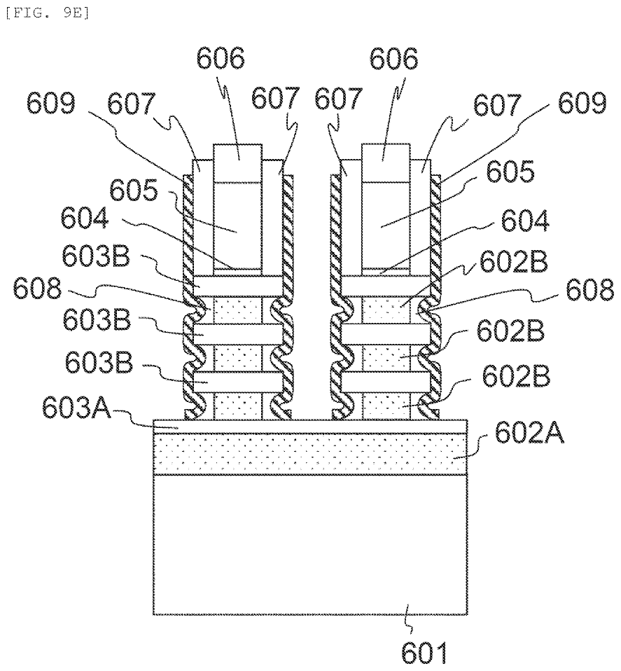

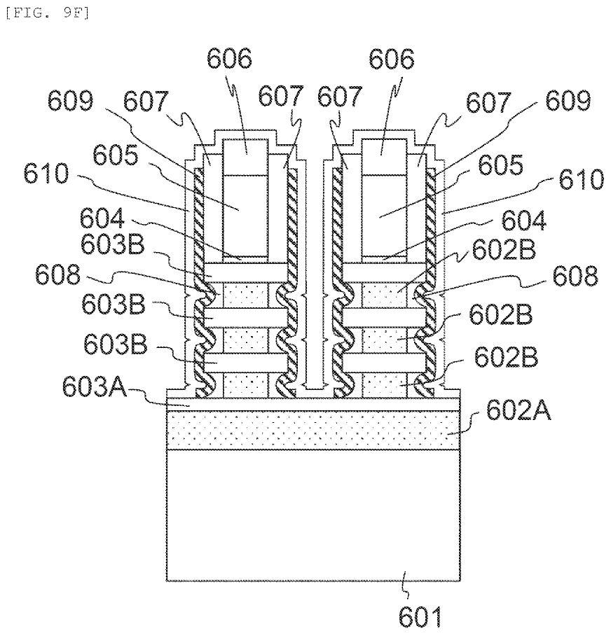

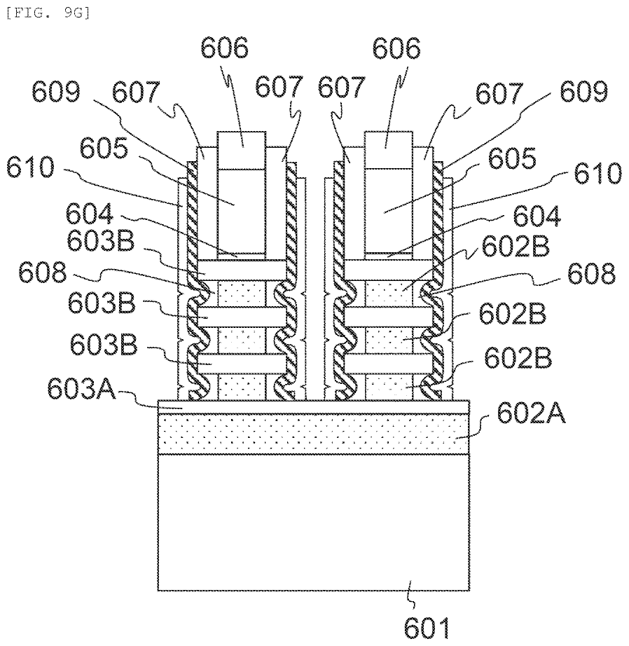

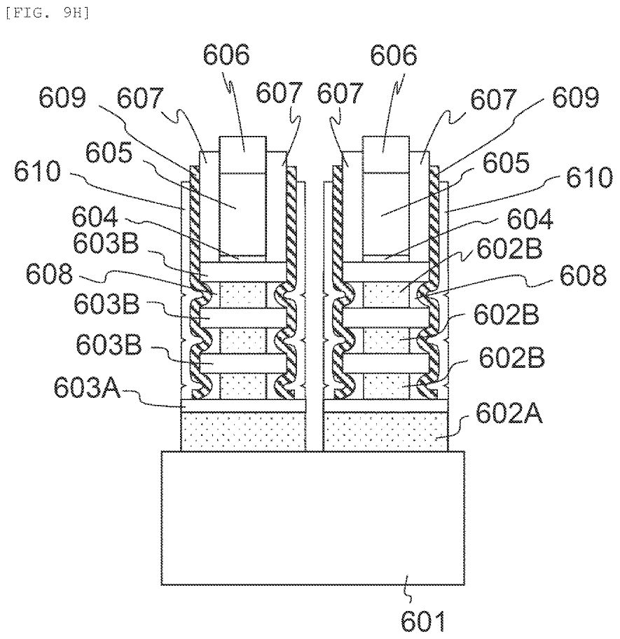

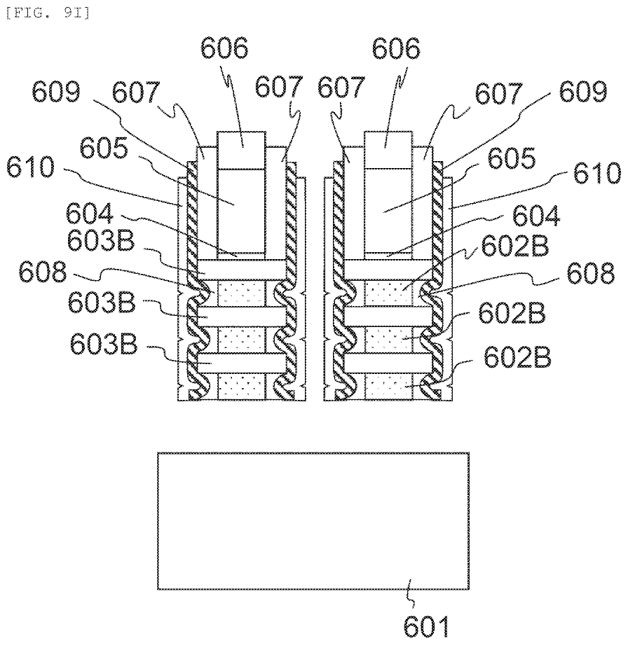

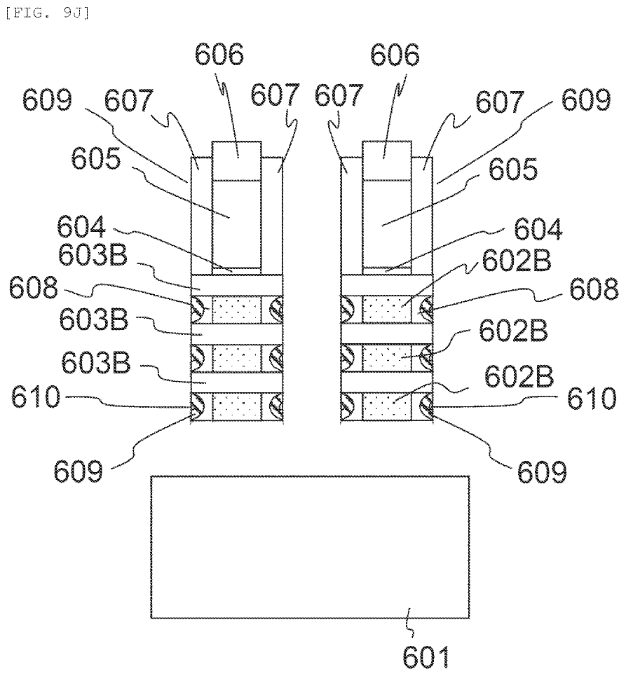

FIG. 1D is a bird's-eye view showing a manufacturing step of the GAA type FET in which the gates and the semiconductor substrate according to Embodiment 1 are electrically isolated from each other.

FIG. 1E is a bird's-eye view showing a manufacturing step of the GAA type FET in which the gates and the semiconductor substrate according to Embodiment 1 are electrically isolated from each other.

FIG. 1F is a bird's-eye view showing a manufacturing step of the GAA type FET in which the gates and the semiconductor substrate according to Embodiment 1 are electrically isolated from each other.

FIG. 1G is a bird's-eye view showing a manufacturing step of the GAA type FET in which the gates and the semiconductor substrate according to Embodiment 1 are electrically isolated from each other.

FIG. 1H is a bird's-eye view showing a manufacturing step of the GAA type FET in which the gates and the semiconductor substrate according to Embodiment 1 are electrically isolated from each other.

FIG. 1I is a bird's-eye view showing a manufacturing step of the GAA type FET in which the gates and the semiconductor substrate according to Embodiment 1 are electrically isolated from each other.

FIG. 1J is a bird's-eye view showing a manufacturing step of the GAA type FET in which the gates and the semiconductor substrate according to Embodiment 1 are electrically isolated from each other.

FIG. 1K is a bird's-eye view showing a manufacturing step of the GAA type FET in which the gates and the semiconductor substrate according to Embodiment 1 are electrically isolated from each other.

FIG. 1L is a bird's-eye view showing a manufacturing step of the GAA type FET in which the gates and the semiconductor substrate according to Embodiment 1 are electrically isolated from each other.

FIG. 1M is a bird's-eye view showing the manufacturing step of the GAA type FET in which the gates and the semiconductor substrate according to Embodiment 1 are electrically isolated from each other.

FIG. 1N is a bird's-eye view showing a manufacturing step of the GAA type FET in which the gates and the semiconductor substrate according to Embodiment 1 are electrically isolated from each other.

FIG. 2A is an enlarged cross-sectional view showing a gate-semiconductor substrate insulating isolation film formation step according to Embodiment 1.

FIG. 2B is an enlarged cross-sectional view showing a gate-semiconductor substrate insulating isolation film formation step according to Embodiment 1.

FIG. 2C is an enlarged cross-sectional view showing a gate-semiconductor substrate insulating isolation film formation step according to Embodiment 1.

FIG. 2D is an enlarged cross-sectional view showing a gate-semiconductor substrate insulating isolation film formation step according to Embodiment 1.

FIG. 3A is a cross-sectional view of an element isolation region showing the manufacturing step of the GAA type FET in which the gates and the semiconductor substrate according to Embodiment 1 are electrically isolated from each other.

FIG. 3B is a cross-sectional view of the element isolation region showing the manufacturing step of the GAA type FET in which the gates and the semiconductor substrate according to Embodiment 1 are electrically isolated from each other.

FIG. 3C is a cross-sectional view of the element isolation region showing the manufacturing step of the GAA type FET in which the gates and the semiconductor substrate according to Embodiment 1 are electrically isolated from each other.

FIG. 3D is a cross-sectional view of the element isolation region showing the manufacturing step of the GAA type FET in which the gates and the semiconductor substrate according to Embodiment 1 are electrically isolated from each other.

FIG. 3E is a cross-sectional view of the element isolation region showing the manufacturing step of the GAA type FET in which the gates and the semiconductor substrate according to Embodiment 1 are electrically isolated from each other.

FIG. 3F is a cross-sectional view of the element isolation region showing the manufacturing step of the GAA type FET in which the gates and the semiconductor substrate according to Embodiment 1 are electrically isolated from each other.

FIG. 4 is a flowchart of manufacturing steps of the GAA type FET in which the gates and the semiconductor substrate according to Embodiment 1 are electrically isolated from each other.

FIG. 5 is a diagram showing a configuration example of a plasma processing apparatus.

FIG. 6A is a bird's-eye view showing a manufacturing step of a GAA type FET in which gates and a semiconductor substrate according to Embodiment 2 are electrically isolated from each other.

FIG. 6B is a bird's-eye view showing a manufacturing step of the GAA type FET in which the gates and the semiconductor substrate according to Embodiment 2 are electrically isolated from each other.

FIG. 6C is a bird's-eye view showing a manufacturing step of the GAA type FET in which the gates and the semiconductor substrate according to Embodiment 2 are electrically isolated from each other.

FIG. 6D is a bird's-eye view showing a manufacturing step of the GAA type FET in which the gates and the semiconductor substrate according to Embodiment 2 are electrically isolated from each other.

FIG. 7A is a cross-sectional view showing a manufacturing step of a GAA type FET in which gates and a semiconductor substrate according to Embodiment 3 are electrically isolated from each other.

FIG. 7B is a cross-sectional view showing a manufacturing step of the GAA type FET in which the gates and the semiconductor substrate according to Embodiment 3 are electrically isolated from each other.

FIG. 7C is a cross-sectional view showing a manufacturing step of the GAA type FET in which the gates and the semiconductor substrate according to Embodiment 3 are electrically isolated from each other.

FIG. 7D is a cross-sectional view showing a manufacturing step of the GAA type FET in which the gates and the semiconductor substrate according to Embodiment 3 are electrically isolated from each other.

FIG. 7E is a cross-sectional view showing a manufacturing step of the GAA type FET in which the gates and the semiconductor substrate according to Embodiment 3 are electrically isolated from each other.

FIG. 7F is a cross-sectional view showing a manufacturing step of the GAA type FET in which the gates and the semiconductor substrate according to Embodiment 3 are electrically isolated from each other.

FIG. 7G is a cross-sectional view showing a manufacturing step of the GAA type FET in which the gates and the semiconductor substrate according to Embodiment 3 are electrically isolated from each other.

FIG. 7H is a cross-sectional view showing a manufacturing step of the GAA type FET in which the gates and the semiconductor substrate according to Embodiment 3 are electrically isolated from each other.

FIG. 7I is a cross-sectional view showing a manufacturing step of the GAA type FET in which the gates and the semiconductor substrate according to Embodiment 3 are electrically isolated from each other.

FIG. 7J is a cross-sectional view showing a manufacturing step of the GAA type FET in which the gates and the semiconductor substrate according to Embodiment 3 are electrically isolated from each other.

FIG. 7K is a cross-sectional view showing a manufacturing step of the GAA type FET in which the gates and the semiconductor substrate according to Embodiment 3 are electrically isolated from each other.

FIG. 8 is a flowchart of manufacturing steps of the GAA type FET in which the gates and the semiconductor substrate according to Embodiment 3 are electrically isolated from each other.

FIG. 9A is a cross-sectional view showing a manufacturing step of the GAA type FET in which the gates and the semiconductor substrate according to Embodiment 4 are electrically isolated from each other.

FIG. 9B is a cross-sectional view showing a manufacturing step of the GAA type FET in which the gates and the semiconductor substrate according to Embodiment 4 are electrically isolated from each other.

FIG. 9C is a cross-sectional view showing a manufacturing step of the GAA type FET in which the gates and the semiconductor substrate according to Embodiment 4 are electrically isolated from each other.

FIG. 9D is a cross-sectional view showing a manufacturing step of the GAA type FET in which the gates and the semiconductor substrate according to Embodiment 4 are electrically isolated from each other.

FIG. 9E is a cross-sectional view showing a manufacturing step of the GAA type FET in which the gates and the semiconductor substrate according to Embodiment 4 are electrically isolated from each other.

FIG. 9F is a cross-sectional view showing a manufacturing step of the GAA type FET in which the gates and the semiconductor substrate according to Embodiment 4 are electrically isolated from each other.

FIG. 9G is a cross-sectional view showing a manufacturing step of the GAA type FET in which the gates and the semiconductor substrate according to Embodiment 4 are electrically isolated from each other.

FIG. 9H is a cross-sectional view showing a manufacturing step of the GAA type FET in which the gates and the semiconductor substrate according to Embodiment 4 are electrically isolated from each other.

FIG. 9I is a cross-sectional view showing a manufacturing step of the GAA type FET in which the gates and the semiconductor substrate according to Embodiment 4 are electrically isolated from each other.

FIG. 9J is a cross-sectional view showing a manufacturing step of the GAA type FET in which the gates and the semiconductor substrate according to Embodiment 4 are electrically isolated from each other.

### DESCRIPTION OF EMBODIMENTS

Hereinafter, embodiments of the present disclosure will be described with reference to the drawings. The present disclosure is not limited to the embodiments described below, and various modifications can be made within the scope of a technical idea thereof. In all the drawings used to describe the embodiments, members having the same function are denoted by the same reference numerals, and repetitive descriptions thereof are omitted. Needless to say, many modifications can be made, such as changing a combination of materials and manufacturing steps relating to the contents disclosed in this embodiment. The drawings are not necessarily to scale, and are schematically drawn with an emphasis being placed on important parts in order to clarify a logic. In order to clarify the description, the drawings may be schematically illustrated as compared with an actual aspect, but are merely examples and do not limit the interpretation of the present disclosure.

### Embodiment 1

In Embodiment 1, a series of steps (also referred to as a step of forming a gate-semiconductor substrate insulating isolation film 11 or a gate-semiconductor substrate insulating isolation film formation step) for electrically isolating the gate and the semiconductor substrate in a manufacturing step (a method for manufacturing a semiconductor device or a plasma processing method) of a gate all around type field effect transistor (a GAA type FET) as a semiconductor device, and a process of stacking a plurality of sidewall protective films made of different materials in the above steps will be described in detail. First, the steps described above will be described with reference to FIGS. 1A to 1N, FIGS. 2A to 2D, FIGS. 3A to 3F, and FIG. 4. The method for manufacturing a semiconductor device or the plasma processing method described in the embodiment is a method for forming the GAA type FET that includes a stacked channel in which thin or sheet-shaped channels are stacked in a direction perpendicular to a substrate in a gate formation region, and that electrically isolates a gate and a semiconductor substrate from each other by an insulating film.

FIGS. 1A to 1N are bird's-eye views showing a process from a step of electrically isolating the gate and the semiconductor substrate to the completion of a FET structure in the manufacturing step of the GAA type FET. FIGS. 1A to 1K show a series of steps from etching of a Si/SiGe (silicon/silicon germanium) stacked film to removal of a second SiGe sacrificial layer and removal of a sidewall protective dielectric film according to this embodiment, FIGS. 1L to 1M show a step of embedding an insulating film (a buried insulating film) for electrically isolating the gate and the semiconductor substrate in a region of the removed second SiGe sacrificial layer. FIG. 1N shows a GAA type FET structure including the buried insulating film (between the gate and the substrate). FIGS. 2A to 2D are enlarged cross-sectional views of a region including a region from a lower portion of the Si/SiGe stacked film to a Si substrate in the steps shown in FIGS. 1D to 1G. FIGS. 3A to 3F show cross-sectional views of gates in element isolation regions other than a channel region of the FET in steps corresponding to the steps in FIGS. 1C to 1K, that is, cross-sections taken along a line AA′ shown in FIG. 1A. FIG. 4 shows a flowchart of the series of manufacturing steps Shown in FIGS. 1A to 1K.

In FIG. 1A, a stacked film in which single crystal SiGe layers (first semiconductor layers) 3 and single crystal Si layers (second semiconductor layers) 4 are alternately single crystal Si substrate (a semiconductor substrate) 1 is formed. The stacked film of the SiGe layers 3 and the Si layers 4 includes a second SiGe sacrificial layer 3A in a lowermost layer, a Si sacrificial layer 4A on the second SiGe sacrificial layer 3A, and first SiGe sacrificial layers 3B and Si channels 4B that are alternately stacked on the Si sacrificial layer 4A. The stacked film of the SiGe layers 3 and the Si layers 4 is formed by epitaxial growth using a chemical vapor deposition (CVD) method or the like, and a Ge composition in each SiGe layer 3 is designed to be the same in the second SiGe sacrificial layer 3A and each of the first SiGe sacrificial layers 3B. The Ge composition may be, for example, 15% to 40%. The second SiGe sacrificial layer 3A and each of the first SiGe sacrificial layers 3B are formed to be lattice-matched to the Si substrate 1, and strain energy caused by a difference in lattice constant between SiGe and Si is contained in each SiGe layer. A film thickness of the second SiGe sacrificial layer 3A, the number of repeated stacked layers of the first SiGe sacrificial layers 3B and the Si channels 4B, and a film thickness of each of the first SiGe sacrificial layers 3B and the Si channels 4B are required to be adjusted according to a condition that the strain energy contained in the SiGe layer does not exceed a critical film thickness at which a defect occurs in the SiGe layers 3, along with characteristics required for the FET. A desirable film thickness is, for example, about 10 nm to 50 nm for the second SiGe sacrificial layer 3A, about 8 nm to 20 nm for the first SiGe sacrificial layer 3B, and about 5 nm to 10 nm for the Si channel 4B. The number of repeated stacked layers of the first SiGe sacrificial layers 3B and the Si channels 4B may be, for example, 3 layers to 6 layers. A film thickness of the Si sacrificial layer 4A may be designed to be about 5 nm to 20 nm, for example. The epitaxial growth using the CVD method may be performed using, for example, monosilane (SiH₄), disilane (Si₂H₆), or germane (GeH4), which is hydrogen-diluted as a source gas. In FIG. 1A, an uppermost layer is the Si channel 4B, but the first SiGe sacrificial layer 3B may be the uppermost layer.

The stacked film of the SiGe layers 3 and the Si layers 4 is processed into a linear pattern in a plan view. A pattern width may be adjusted to, for example, about 5 nm to 15 nm in the case of forming a thin nanowire channel, and may be adjusted to, for example, about 10 nm to 100 nm in the case of forming a sheet-shaped nanosheet channel. In the nanowire channel, since a peripheral length of the channel is short, controllability by a gate is increased, while a current value of a driving current is small. On the other hand, in the nanosheet channel, although controllability by a gate is slightly worse than that of the nanowire, a large driving current can be obtained.

A channel shape is determined from the viewpoint of an application of a required device. The linear pattern is a periodic pattern or a pattern similar thereto. For example, in the case of using a laser using an argon fluoride (ArF) gas as a light source for lithography, when a pattern period is, for example, 40 nm or more and 80 nm or less, self-aligned double patterning (SADP) can be used. When the pattern period is, for example, 20 nm or more and 40 nm or less, self-aligned quadruple patterning (SAQP) can be used in case of the ArF lithography. In the case of using extreme ultraviolet (EUV) exposure with a wavelength of 13.5 nm for the lithography, single patterning can be used up to a pattern period of, for example, 40 nm. When the pattern period is, for example, 20 nm or more and 40 nm or less, the SADP can be used in case of the EUV lithography.

After the pattern of the stacked film of the SiGe layers 3 and the Si layers 4 is formed, a shallow trench isolation (STI) insulating film (referred to as an STI insulating film) 2 for forming an isolation region is is deposited in a trench of the Si substrate 1 which partially patterned, and the STI insulating film 2 is etched back to obtain a structure of the insulating film 2 shown in FIG. 1A. The STI insulating film 2 is formed using the CVD method or the like. A material of the STI insulating film 2 may be a silicon oxide film (SiO₂), a silicon oxynitride film (SiON), a silicon carbon oxide film (SiCo), or the like. An upper surface of the STI insulating film 2 after the etch back may be set at any position, but in the most desirable form, an etching amount may be adjusted such that the upper surface is located between an upper end and a lower end of the second SiGe sacrificial layer 3A.

On the pattern of the stacked film of the SiGe layers 3 and the Si layers 4, dummy gate dielectric films 5 each made of SiO₂ or an equivalent insulating film, dummy gates 6 each made of non-crystalline (amorphous) Si or polycrystalline (poly) Si, and hard masks 7 each made of dielectric layer such as SiO₂ or a silicon nitride film (Si₃N₄), SiON or the like are formed. Each dummy gate dielectric film 5 may be formed using, for example, the CVD method, or may be formed by oxidizing the SiGe layer 3 and the Si layer 4 using a thermal oxidation method or a plasma oxidation method. A film thickness of the dummy gate dielectric film 5 is preferably within a range of 1 nm to 3 nm, for example. The dummy gates 6 and the hard masks 7 may be formed using a film forming method such as the CVD method. Film thicknesses of each dummy gate 6 and each hard mask 7 are preferably adjusted within a range of, for example, 20 nm to 200 nm. The dummy gate dielectric films 5, the dummy gates 6, and the hard masks 7 are patterned in a direction perpendicular to the pattern of the stacked film of the SiGe layers 3 and the Si layers 4. The patterning is performed by selectively using a method such as the SADP or the single patterning in accordance with a gate pitch. For example, the gate pitch is set to 40 nm to 70 nm, a width of each dummy gate 6, that is, a gate length is set to 10 nm to 30 nm, and the hard masks 7, the dummy gates 6, and the dummy gate insulating films 5 are etched along the pattern. Here, the etching of the hard masks 7 and the dummy gates 6 may use, for example, vertical etching using dry etching. The etching of the dummy gate dielectric films 5 may use isotropic etching using, for example, dry etching or wet etching. The dummy gate dielectric films 5 may be etched not in this step shown in FIG. 1A but after the spacer etching in FIG. 1B. After the hard masks 7, the dummy gates 6, and the dummy gate dielectric films 5 are etched, gate sidewall spacers (gate sidewall spacer films) 8 are deposited using the CVD method or the like to obtain a structure shown in FIG. 1A. As each gate sidewall spacer 8, for example, a SiON film, a silicon carbon oxynitride film (SiOCN), or a SiCO film, which is a low dielectric constant film, may be used. A film thickness of the gate sidewall spacer 8 in a horizontal direction is adjusted within a range of 5 nm to 15 nm.

From the structure shown in FIG. 1A, the gate sidewall spacers 8 are subjected to anisotropic etching in a vertical direction to obtain a structure shown in FIG. 1B. In the anisotropic etching of the gate sidewall spacers 8, when the SiCO film is used for the gate sidewall spacers 8, for example, a mixed gas obtained by adding nitrogen (N₂) gas to tetrafluoromethane (CF₄) and octafluorocyclobutane (C₄F₈) may be used. When the SiOCN film is used for the gate sidewall spacers for example, a mixed gas of fluoromethane (CH₃F), oxygen (O₂), and helium (He) may be used in the anisotropic etching of the gate sidewall spacers 8. The etching is performed under a condition that selective etching is performed on the pattern of the stacked film of the SiGe layers 3 and the Si layers 4. When the dummy gate insulating films 5 are not etched in FIG. 1A, the etching of the gate sidewall spacers 8 is performed under etching conditions using the dummy gate insulating films 5 as stoppers. After the etching, the etching amount in this etching is adjusted such that an upper end of each gate sidewall spacer 8 is located between an upper end and a lower end of hard mask 7. That is, after this etching, sidewalls of the dummy gates 6 are all adjusted to be covered with the gate sidewall spacers 8. This step shown in FIG. 1B corresponds to step 101 of a process flowchart in FIG. 4.

In FIG. 1C, anisotropic etching of the pattern of the stacked film of the SiGe layers 3 and the Si layers 4 in the vertical direction is performed along the sidewalls of the gate sidewall spacers 8. In the anisotropic etching, it is preferable that an etching time is adjusted to etch the stacked film of the first SiGe sacrificial layers 3B and the Si channels 4B and the Si sacrificial layer 4A, and the etching is terminated in a structure of the stacked film in a state where the second SiGe sacrificial layer 3A is exposed. A depth at which the second SiGe sacrificial layer 3A is etched by over etching is preferably adjusted within a range of 0 nm to 40 nm, for example. In this etching, for example, chlorine (Cl₂) or CF₄, a gas similar to Cl₂ or CF₄, a mixed gas of Cl₂ and CF₄, or a gas obtained by containing nitrogen trifluoride (NF₃) or O₂ in Cl₂ and CF₄ may be used. The etching of the stacked film of the SiGe layers 3 and the Si layers 4 in this step corresponds to step 102 of the process flowchart in FIG. 4, and may be performed continuously in a chamber of the same apparatus after the etching step 101 of the gate sidewall spacers 8 shown in FIG. 1B. FIG. 3A shows a cross section of a gate in the element isolation region (the line AA′ in FIG. 1A) other than the channel region of the FET after this step.

Thereafter, a first protective dielectric film 9 is deposited by a film formation technique using an atomic layer deposition (ALD) method to obtain a structure shown in FIG. 1D. The protective dielectric film 9 is deposited on upper surfaces and the sidewalls of the hard masks 7 and the gate sidewall spacers 8, sidewalls of the stacked film including the exposed first SiGe sacrificial layers 3B and the Si channels 4B, sidewalls of the Si sacrificial layer 4A, an upper surface of the second SiGe sacrificial layer 3A, and the STI insulating film 2. A material of the protective insulating film 9 is preferably an insulating film containing nitrogen in consideration of an etching selection ratio between the stacked film including the SiGe layers 3 and the Si layers 4 and the peripheral STI insulating film 2, and is preferably a film containing a silicon element and a nitrogen element, for example, a Si₃N₄ film or a SiON film similar thereto. A film thickness of the protective dielectric film 9 is controlled to about 2 nm to 3 nm. The ALD method has an advantage of being able to form a thin film with good controllability even in a complicated shape having many irregularities. When the protective dielectric film 9 is a Si₃N₄ film formed by the ALD method, as a source of Si, for example, bis(tertbutylamino)silane (BTBAS), bis(diethylamino)silane (BDEAS), or dichlorosilane (SiH₂Cl₂) is used, and as a source of nitrogen, a gas containing nitrogen such as N₂ gas, a mixed gas of N₂ gas and hydrogen (H₂) gas, or ammonia (NH₃) gas is used. The protective dielectric film 9 may be a film containing no nitrogen such as SiO₂ or may be formed by the CVD method or the like. In this step, FIG. 2A shows an enlarged view including a portion from the lower portion of the stacked film of the first SiGe sacrificial layers 3B and the Si channels 4B to the second SiGe sacrificial layer 3A in FIG. 1D. The sidewalls of the stacked film including the first SiGe sacrificial layers 3B and the Si channels 4B and of the Si sacrificial layer 4A have a tapered shape slightly inclined from the vertical direction at the bottom of the pattern in many cases. This reflects a characteristic of the dry etching during the pattern formation shown in FIG. 1C, and is due to the fact that reaction products or source gases are easily deposited on the sidewalls during the etching. A taper angle is controlled by an ion energy, an etching gas, a pressure in an etching chamber, and the like during the etching, and is adjusted in consideration of damage to the underlying second SiGe sacrificial layer 3A. An angle (θ1 in FIG. 2A) between the sidewalls and the upper surface of the second SiGe sacrificial layer 3A is, for example, within a range of 80 degrees to 90 degrees. In FIG. 1C, a width of a trench pattern formed in the Si sacrificial layer 4A and the stacked film including the first SiGe sacrificial layers 3B and the Si channels 4B is, for example, 20 nm when the gate pitch is 56 nm, the gate length is 20 nm, and the film thickness of the gate sidewall spacer 8 in the horizontal direction is 8 nm. The width of the trench pattern is expected to be further reduced together with the scaling of the transistor, and is expected to be, for example, about 10 nm to 15 nm in the future. In this case, considering the taper angle, it is assumed that a width of a trench pattern at the bottom of the trench is, for example, about 10 nm or less. When the protective insulating film 9 is formed in the narrow pattern as described above, it is assumed that a film thickness (t2 in FIG. 2A) in the vertical direction at the bottom of the trench is larger than a film thickness (t1 in FIG. 2A) in the horizontal direction at the sidewall. When the film thickness t1 of the protective dielectric film 9 in the horizontal direction on the sidewall of the pattern is, for example, 2 nm to 3 nm, it is expected that the film thickness t2 in the vertical direction at the bottom of the trench is, for example, 3 nm to 6 nm. This step shown in FIG. 1D corresponds to step 103 of the process flowchart in FIG. 4, and may be performed continuously in the chamber of the same apparatus after an etching step 102 of the Si sacrificial layer 4A and the stacked film including the first SiGe sacrificial layers 3B and the Si channels 4B shown in FIG. 1C. FIG. 3B shows a cross section of a gate in the element isolation region (the line AA′ in FIG. 1A) other than the channel region of the FET after this step.

In the step shown in FIG. 1E, the protective dielectric film 9 is etched in the vertical direction. The etching is performed under selective etching conditions selective to the hard masks 7, the gate sidewall spacers 8, the second SiGe sacrificial layer 3A, and the STI insulating film 2. For example, when the protective dielectric film 9 is a Si₃N₄ film, for example, a gas obtained by adding Cl₂ or the like to a mixed gas of a halogen-based gas such as CF₄ or C₄F₈ and O₂, or a gas similar thereto may be used as the etching gas. By this etching, the upper surface of the second SiGe sacrificial layer 3A is exposed. FIG. 2B is an enlarged view including a portion from the lower portion of the stacked film of the first SiGe sacrificial layers 3B and the Si channels 4B to the second SiGe sacrificial layer 3A in the above step. In this etching, the etching time is determined in consideration of the film thickness of the protective dielectric film 9 in the vertical direction at the bottom of the trench. Since the film thickness of the protective dielectric film 9 in the vertical direction on the bottom of the trench is larger than the film thickness of the protective insulating film 9 in the horizontal direction on the sidewall of the trench, a part of the protective dielectric film 9 on the sidewall is also removed by etching at the bottom of the trench after etching, and as shown in FIG. 2B, a part of the Si sacrificial layers 4A and the first SiGe sacrificial layers 3B may be exposed. At this time, a lower portion of the protective dielectric film 9 has an eave structure as shown in FIG. 2B, and an angle θ2 formed by the eave and the sidewall of the stacked film including the Si sacrificial layer 4A, the first SiGe sacrificial layers 3B, and the Si channels 4B is an acute angle of 90 degrees or less. FIG. 3C shows a cross section of a gate in the element isolation region (the line AA′ in FIG. 1A) other than the channel region of the FET after this step. The STI insulating film 2 is also slightly etched by the over etching in the etching of the protective dielectric film 9. This step shown in FIG. 1E corresponds to step 104 of the process flowchart in FIG. 4, and may be performed continuously in the chamber of the same apparatus after a film forming step 103 of the protective dielectric film 9 shown in FIG. 1D.

Subsequent to the above step, a second protective dielectric film 10 is deposited on the first protective dielectric film 9 using the ALD method to obtain a structure shown in FIG. 1F. A stacked film of protective dielectric films is formed by the first protective dielectric film 9 and the second protective dielectric film 10. In the stacked film of the protective dielectric films, a lower layer side is the first protective dielectric film 9, and an upper layer side is the second protective dielectric film 10. A dielectric film material of the first protective dielectric film 9 and a dielectric film material of the second protective dielectric film 10 are different from each other. The second protective dielectric film 10 is deposited on upper surfaces and sidewalls of the hard masks 7, the gate sidewall spacers 8, and the protective dielectric film 9, the upper surface of the second SiGe sacrificial layer 3A, and the STI insulating film 2. FIG. 2C shows an enlarged view including a portion from the lower portion of the stacked film of the first SiGe sacrificial layers 3B and the Si channels 4B to the second SiGe sacrificial layer 3A after the second protective dielectric film 10 is deposited. In FIG. 2C, a film thickness (t3 in FIG. 2C) of the second protective dielectric film 10 in the horizontal direction is equal to (t3=t1) or smaller (t3<t1) than the film thickness t1 of the first protective dielectric film 9 in the horizontal direction. When the film thickness t1 is, for example, 2 nm to 3 nm, it is desirable that the film thickness t3 is, for example, 1 nm to 3 nm. In the step shown in FIG. 2B, when the Si sacrificial layer 4A and a lower portion of the sidewall of the stacked film including the first SiGe sacrificial layers 3B and the Si channels 4B are exposed, the second protective dielectric film 10 is also deposited on the eave formed in the lower portion of the first protective dielectric film 9 and the exposed Si sacrificial layer 4A and the sidewall of the stacked film including the first SiGe sacrificial layers 3B, and the Si channels 4B by the source gas passing through a flow path a1. Since the second protective dielectric film 10 is deposited conformally, in a lower portion of the eave of the first protective dielectric film 9, a film formed in the vertical direction from the lower portion of the eave and a film formed in the horizontal direction on the Si sacrificial layer 4A and the sidewall of the stacked film including the first SiGe sacrificial layers 3B and the Si channels 4B overlap each other, and a film thickness (t4 in FIG. 2C) of the second protective dielectric film 10 in this area is larger than the film thickness t3 of the second protective dielectric film 10 in the horizontal direction on a sidewall of the first protective insulating film 9. By setting the film thickness t3 to be smaller than the film thickness t1, a film thickness (t5 in FIG. 2C) of the second protective dielectric film 10 in the vertical direction on the second SiGe sacrificial layer 3A is equal to (t3+t1=t5) a sum of the film thickness t3 and the film thickness t1 or smaller (t3+t1>t5) than the sum of the film thickness t3 and the film thickness t1. As the second protective dielectric film 10, a film that can be conformally formed with good controllability even in a complicated shape having finer irregularities is used. The second protective dielectric film 10 is a film containing an aluminum element and an oxygen element, for example, an aluminum oxide (Al₂O₃) film or an aluminum oxynitride (AlON) film similar thereto. In the case of forming the Al₂O₃ film, for example, trimethyl aluminum (TMA) (Al(CH₃)₃) may be used as a raw material of aluminum (Al), and vaporized water (H₂O) may be used as a raw material of oxygen. Since a precursor made of Al(CH₃)₃ has high reactivity with a water acid group (OH group) formed on a surface by the supply of H₂O, it is possible to form an Al₂O₃ film with good coverage on a surface having irregularities. Accordingly, the Al₂O₃ film is also formed conformally inside the pattern having a narrow opening in FIG. 2C. The second protective dielectric film 10 may be an oxide film or a nitride film not containing Al, or may be formed using the CVD method or the like. This step shown in FIGS. 1F and 2C corresponds to step 105 of the process flowchart in FIG. 4, and may be performed continuously in the chamber of the same apparatus after an etching step 104 of the first protective dielectric film 9 shown in FIGS. 1E and 2B. FIG. 3D shows a cross section of a gate in the element isolation region (the line AA′ in FIG. 1A) other than the channel region of the FET after this step.

Next, in the step shown in FIG. 1G, the second protective dielectric film 10 is etched in the vertical direction. The etching is performed under selective etching conditions selective to the first protective dielectric film 9, the hard masks 7, the gate sidewall spacers 8, the second SiGe sacrificial layer 3A, and the STI insulating film 2. For example, when the second protective dielectric film 10 is an Al₂O₃ film, for example, boron trichloride (BCl₃), a mixed gas of BCl₃ and Cl₂, a gas obtained by mixing argon (Ar), N₂, O₂ with these gases, or a gas similar to these gases may be used as the etching gas. By this etching, the upper surface of the second SiGe sacrificial layer 3A is exposed. FIG. 2D is an enlarged view including a portion from the lower portion of the stacked film of the first SiGe sacrificial layers 3B and the Si channels 4B to the second SiGe sacrificial layer 3A in the above step. At the time of performing this etching, even when ions generated from the etching gas are incident on the substrate 1 in an oblique direction from the vertical direction, the ions are reflected by the sidewalls of the first protective dielectric film 9 to change an angle (a2 in FIG. 2D). As shown in FIG. 2C, an opening width of an opening pattern formed in the Si sacrificial layer 4A, the first SiGe sacrificial layers 3B, and the Si channels 4B is the smallest in a vicinity of the eave of the first protective dielectric film 9 after the formation of the second protective dielectric film 10. Therefore, etching gas ions reflected by the sidewalls of the first protective dielectric film 9 are almost entirely consumed in the etching of the second protective dielectric film 10 in the vertical direction, and the second protective dielectric film 10 deposited on the pattern sidewall of the lower portion of the eave is not etched. By the above process, it is possible to open an upper portion of the second SiGe sacrificial layer 3A while protecting a sidewall of the opening pattern formed in the Si sacrificial layer 4A and the first SiGe sacrificial layers 3B and the Si channels 4B. FIG. 3E shows a cross section of a gate in the element isolation region (the line AA′ in FIG. 1A) other than the channel region of the FET after this step. The STI insulating film 2 is also slightly etched by the over etching in the etching of the second protective dielectric film 10. This step shown in FIGS. 1G and 2D corresponds to step 106 of the process flowchart in FIG. 4, and may be performed continuously in the chamber of the same apparatus after a film forming step 105 of the second protective dielectric film 10 shown in FIGS. 1F and 2C. A cycle process (also referred to as a gas or film forming condition) shown in steps 103 and 104 and steps 105 and 106 in FIG. 4 is not limited to two cycles, and may be repeated a plurality of times. That is, when a combination of the film forming steps (103 and 105) as a first step and the etching steps (104 and 106) as a second step is considered as one cycle, in FIG. 4, the combination of the film forming steps and the etching steps is performed for two cycles (a first cycle is steps 103 and 104, a second cycle is steps 105 and 106) to form a third step. In steps 103 and 104 of the first cycle and steps 105 and 106 of the second cycle, the gas and the film forming condition may be changed. The number of cycles of the film forming steps (103 and 105) and the etching steps (104 and 106) is not limited to two cycles, and may be repeated a plurality of times.

In the step (a fourth step) shown in FIG. 1H, the second SiGe sacrificial layer 3A is etched in the vertical direction. The etching is performed under selective etching conditions selective to the second protective dielectric film 10, the first protective dielectric film 9, the hard masks 7, the gate sidewall spacers 8, the STI insulating film 2, and the Si substrate 1. As the etching gas, for example, a gas containing a halogen-based element such as HBr, CF₂Cl₂, bromotrifluoromethane (CF₃Br), or a gas containing about 1% to 5% of CF₄ in HBr, a mixed gas thereof, or a gas obtained by adding O₂, a rare gas such as Ar or He, an inert gas such as N₂ or the mixed gas thereof to these gases may be used. Conditions such as a gas flow rate ratio, a combination of the ion energy and the etching gas during the etching, a pressure in the etching chamber may be adjusted such that the etching of the second SiGe sacrificial layer 3A maintains the verticality and an etching rate is about 1 time to 10 times an etching rate of the Si substrate 1. This step shown in FIG. 1H corresponds to step 107 of the process flowchart in FIG. 4, and may be performed continuously in the chamber of the same apparatus after an etching step 106 of the second protective insulating film 10 shown in FIGS. 1G and 2D.

Next, in a step (the fourth step) shown in FIG. 1I, the second SiGe sacrificial layer 3A is removed by isotropic etching. The etching is performed under selective etching conditions selective to the second protective dielectric film 10, the first protective dielectric film 9, the hard masks 7, the gate sidewall spacers 8, the STI insulating film 2, the Si substrate 1, and the Si sacrificial layer 4A. As the etching gas, for example, a gas containing fluorine such as sulfur hexafluoride (SF₆), CF₄, or NF₃, a mixed gas thereof, or a gas obtained by adding O₂, a rare gas such as Ar or He, an inert gas such as N₂ or the mixed gas thereof to these gases may be used. Conditions such as a gas flow rate ratio, a combination of the ion energy and the etching gas during the etching, a pressure in the etching chamber may be adjusted such that the etching of the second SiGe sacrificial layer 3A is isotropic and an etching rate is, for example, about 1 time to 200 times the etching rate of the Si substrate 1. This step shown in FIG. 1I corresponds to step 108 of the process flowchart in FIG. 4, and may be performed continuously in the chamber of the same apparatus after an etching step 107 of the second SiGe sacrificial layer 3A in the vertical direction shown in FIG. 1H. This step shown in FIG. 1I may be performed continuously in the chamber of the same apparatus after the etching step 106 of the second protective dielectric film 10 shown in FIG. 1G by omitting the etching step 107 of the second SiGe sacrificial layer 3A in the vertical direction shown in FIG. 1H.

In a step (the fourth step) shown in FIG. 1J, the Si sacrificial layer 4A is removed by isotropic etching. The etching is performed under selective etching conditions selective to the second protective dielectric film 10, the first protective dielectric film 9, the hard masks 7, the gate sidewall spacers 8, the STI insulating film 2, and the first SiGe sacrificial layers 3B. As the etching gas, for example, a gas obtained by adding a gas such as H₂ or O₂ or N₂ or a mixed gas thereof to a gas containing fluorine such as SF₆ or CF₄ or NF₃ or a mixed gas thereof may be used. Conditions such as a gas flow rate ratio, a combination of the ion energy and the etching gas during the etching, a pressure in the etching chamber may be adjusted such that the etching of the Si sacrificial layer 4A is isotropic and an etching rate thereof is, for example, about 1 time to 100 times an etching rate of each first SiGe sacrificial layer 3B. This step shown in FIG. 1J corresponds to step 109 of the process flowchart in FIG. 4, and may be performed continuously in the chamber of the same apparatus after an etching removal step 108 of the second SiGe sacrificial layer 3A shown in FIG. 1I.

In the step shown in FIG. 1K, the second protective dielectric film 10 and the first protective dielectric film 9 are sequentially removed by isotropic etching. The etching of the second protective dielectric film 10 is performed under selective etching conditions selective to the first protective dielectric film 9, the hard masks 7, the gate sidewall spacers 8, the STI insulating film 2, lower surfaces of the first SiGe sacrificial layers 3B, and the Si substrate 1. For example, when the second protective dielectric film 10 is an Al₂O₃ film, a mixed gas of O₂, BCl₃, and Ar, or a gas similar thereto may be used as the etching gas. This etching is performed under the condition that the second protective dielectric film 10 is etched with a time that is once or twice an etching time required for etching the second protective dielectric film 10 by a film thickness and almost all of the second protective dielectric film 10 is removed. After the second protective dielectric film 10, the first protective dielectric film 9 is removed by isotropic etching. This etching is performed under selective etching conditions selective to the hard masks 7, the gate sidewall spacers 8, the STI insulating film 2, the lower surfaces and sidewalls of the first SiGe sacrificial layers 3B, the Si channels 4B, and the Si substrate 1. For example, when the protective dielectric film 9 is a Si₃N₄ film, as the etching gas, a gas such as trifluoromethane (CHF₃), difluoromethane (CH₂F₂), or CH₃F may be used, or a mixed gas of a fluorocarbon-based gas such as CF₄ or C₄F₈ and H₂, or a gas similar thereto may be used. As in the etching of the second protective dielectric film 10, this etching is performed under the condition that the first protective dielectric film 9 is etched with a time that is once or twice an etching time required for etching the first protective dielectric film 9 by a film thickness and almost all of the first protective dielectric film 9 is removed. By this step, the sidewalls of the first SiGe sacrificial layers 3B and the Si channels 4B are exposed. This step corresponds to step 110 of the process flowchart in FIG. 4, and may be performed continuously in the chamber of the same apparatus after an etching removal step 109 of the Si sacrificial layer 4A shown in FIG. 1J. That is, steps from a gate sidewall spacer vertical etching step 101 (FIG. 1B) to a first and second protective dielectric films isotropic etching removal step 110 (FIG. 1K) in FIG. 4 can be performed continuously in the chamber of the same apparatus. FIG. 3F shows a cross section of a gate in the element isolation region (the line AA′ in FIG. 1A) other than the channel region of the FET in a step corresponding to FIG. 1K. Due to an influence of the over etching by the vertical etching of the first protective dielectric film 9 (FIGS. 1E and 3C) and the vertical etching of the second protective dielectric film 10 (FIGS. 1G and 3E), the upper surface of the STI insulating film 2 has a curved shape in a region of a gap between the adjacent gate sidewall spacers 8. Since this shape contributes to the deposition of an isotropic film when an interlayer insulating film (a second interlayer insulating film 16 in FIG. 1N) is deposited in a subsequent step, a film density of the interlayer insulating film is kept constant at the bottom of the gap. Therefore, an effect of preventing generation of a cavity in the interlayer insulating film due to a decrease in the film density is achieved.

Subsequent to the series of steps, in the step shown in FIG. 1L, a gate-substrate isolation insulating film 11 as a buried insulating film (the first insulating film) is deposited. The gate-substrate isolation insulating film 11 is formed using the CVD method or the like, and after the formation of the gate-substrate isolation insulating film 11, a planarization process of planarizing a surface of the gate-substrate isolation insulating film 11 is performed by chemical mechanical polishing (CMP) using the hard masks 7 as stoppers. A material of the gate-substrate isolation insulating film 11 may be, for example, SiO₂, SiON, or SiCO. By the above formation, regions where the second SiGe sacrificial layer 3A and the Si sacrificial layer 4A are present are filled with the gate-substrate isolation insulating film 11.

In the subsequent steps, the gate-substrate isolation insulating film 11 is etched back to obtain a structure shown in FIG. 1M. An etching amount may be adjusted such that an upper surface of the gate-substrate isolation insulating film 11 after the etch back is located, for example, between a lower surface and an upper surface of a lowermost first SiGe sacrificial layer 3B. By this step, a structure (a structure in which the stacked film and the Si substrate 1 are isolated from each other by the gate-substrate isolation insulating film 11) in which the Si substrate 1 and the stacked film including the first SiGe sacrificial layers 3B and the Si channels 4B are electrically isolated from each other by the gate-substrate isolation insulating film 11 is formed. The gate-substrate isolation insulating film 11 can also be referred to as a buried insulating film 11.

Thereafter, a transistor structure shown in FIG. 1N is obtained through a GAA type FET formation process. This process includes formation of gate sidewall inner spacers 12, formation of source and drains 15, formation of the second interlayer insulating films 16, removal of the hard masks 7 and the dummy gates 6, and the dummy gate dielectric films 5 and the first SiGe sacrificial layers 3B by etching, formation of gate dielectric films 13 and gate metals 14, formation of contact barrier metals 17 and contact metals 18, and a subsequent metal wiring step.

The gate sidewall inner spacers 12 are formed, for example, through a step of forming trenches by selectively performing isotropic etching on the first SiGe sacrificial layers 3B with respect to the Si channels 4B and other peripheral films thereof to remove a part of the first SiGe sacrificial layers 3B and then depositing, in the trenches formed in the first SiGe sacrificial layers 3B, low dielectric constant films formed using the CVD method or the like, and a step of removing a part of the low dielectric constant films by isotropic etching. Accordingly, the gate sidewall inner spacers 12 formed inside the trenches of the first SiGe sacrificial layers 3B can be obtained. As the low dielectric constant films that form the gate sidewall inner spacers 12, for example, a SiCO film, a SiOCN film, a SiON film, a film similar thereto, or a stacked film thereof may be used. In the isotropic etching of the first SiGe sacrificial layers 3B, an etching time thereof may be adjusted such that an etching amount of each first SiGe sacrificial layer 3B is, for example, about 1 nm to 10 nm using the same conditions as those of the isotropic etching of the second SiGe sacrificial layer 3A shown in FIG. 1I. In the isotropic etching of the low dielectric constant films, for example, when each low dielectric constant film is a SiCO film, for example, a mixed gas of N₂ or O₂ and a gas containing fluorine such as CHF₃, CH₂F₂, CH₃F, NF₃, or a gas similar thereto may be used as the gas during the etching.

The source and drains 15 are formed by, for example, selective growth of Si or SiGe on the sidewalls of the Si channels 4B by using epitaxy. By patterning, different Si or SiGe films are formed on an n-type FET region and a p-type FET region, respectively. Here, Si doped with an n-type impurity such as phosphorus (P) or arsenic (As) may be selectively grown in the n-type FET region, and SiGe doped with a p-type impurity such as boron (B) may be selectively grown in the p-type FET region.

The second interlayer insulating films 16 are formed using the CVD method or the like. For example, SiO₂, SiON, or SiCO may be used as a material of each second interlayer insulating film 16. In the removal of the hard masks 7, the dummy gates 6, the dummy gate dielectric films 5, and the first SiGe sacrificial layers 3B by etching, an etching gas and an etching condition suitable for each material are used. When hard mask 7 is a Si₃N₄ film, a gas such as CHF₃, CH₂F₂, or CH₃F may be used as the etching gas. In the etching of the dummy gates 6 each made of poly-Si, for example, dry etching using a gas such as SF₆, CF₄, HBr, or a gas similar thereto may be performed, or wet etching using an aqueous solution of tetramethyl ammonium hydroxide (TMAH) or the like may be performed. The dummy gate dielectric films 5 may be removed by, for example, wet etching using a hydrofluoric acid (HF) aqueous solution or the like, and the subsequent removal of the first SiGe sacrificial layers 3B by etching may be performed under the same conditions as those for the isotropic etching of the second SiGe sacrificial layer 3A shown in FIG. 1I. As gate dielectric film 13, for example, material with a high dielectric constant such as hafnium oxide (HfO₂) or Al₂O₃ or a stacked film of these high dielectric materials may be used.

Each gate metal 14 may be formed of, for example, a p-work function control metal that determines a threshold voltage of a p-type FET, an n-work function control metal that determines a threshold voltage of an n-type FET, and a gate buried metal. For a p-work function control metal film, for example, titanium nitride (TiN), a tantalum nitride (TaN) film, or a metal compound having a work function equivalent to that of titanium nitride (TiN) or tantalum nitride (TaN) may be used. For an n-work function control metal film, for example, a metal in which carbon (C), oxygen (O), nitrogen (N), or the like is contained in titanium aluminum (TiAl) or TiAl, or a metal compound having a work function equivalent to that of the metal may be used. A gate filling metal film is deposited for the purpose of reducing a metal resistance in the gate, and can use, for example, a material such as tungsten (W). The gate metal 14 is formed by, for example, the CVD method or the ALD method.

The contact barrier metals 17 and the contact metals 18 are patterned to partially etch the second interlayer insulating films 16, and are formed in portions of the n-type FET region and the p-type FET region where the source and drains 15 are exposed. For example, TiN, TaN, or a metal similar thereto may be used for each contact barrier metal 17, and, for example, W or cobalt (Co) may be used for each contact metal 18. A film thickness of the contact barrier metal 17 is designed to be, for example, about 1 nm to 3 nm. In the GAA type FET structure shown in FIG. 1N, the gate metal 14 and the Si substrate 1 are electrically isolated by the gate-substrate isolation insulating film 11, and the Si substrate 1 is prevented from operating as a parasitic FET.

By performing a step of forming the gate-semiconductor substrate isolation film 11 (the steps shown in FIGS. 1A to 1N) in a plasma processing apparatus having an ALD film forming function and an anisotropic and isotropic etching control function, a series of steps shown in FIG. 4, that is, a continuous process from the gate sidewall spacer vertical etching (101 in FIG. 4) shown in FIG. 1B to the first and second protective dielectric films isotropic etching removal (110 in FIG. 4) shown in FIG. 1K can be performed continuously in the same plasma processing apparatus. The plasma processing apparatus may be any of an etching apparatus using inductively coupled plasma (ICP), an etching apparatus using capacitively coupled plasma (CCP), and an etching apparatus using microwave electron cyclotron resonance (ECR) plasma.

As an example, FIG. 5 shows a configuration of a plasma processing apparatus 200 using microwave ECR plasma. The plasma processing apparatus 200 includes a processing chamber (a chamber) 201, and the processing chamber 201 is connected to a vacuum exhaust equipment (not shown) via a vacuum exhaust port 202, and an inside of the processing chamber 201 is maintained at a vacuum of about 0.1 Pa to 10 Pa during plasma processing. The processing chamber 201 is provided with a window portion 203 having a function of transmitting microwaves and a function of hermetically sealing the processing chamber 201, and a perforated plate 204 for shielding ions. The processing chamber 201 is divided into an upper portion 201A of the processing chamber 201 and a lower portion 201B of the processing chamber 201 by the perforated plate 204. The window portion 203 is made of a material that transmits microwaves, and uses a dielectric such as quartz. The perforated plate 204 may have a plurality of holes, and the perforated plate 204 may be made of a dielectric material such as quartz or alumina.

A gas supply mechanism includes a gas source 205, a gas supply device 206, and a gas introduction port 207, and supplies a source gas used for the plasma processing. The gas source 205 has a plurality of gas species necessary for the processing. The gas supply equipment 206 includes a control valve that controls supply and cutoff of gas, and a mass flow controller that controls a flow rate of the gas. The gas introduction port 207 is provided between the window portion 203 and the perforated plate 204.

A waveguide 209 through which electromagnetic waves propagate is connected to the upper portion of the processing chamber 201, and a plasma generating high-frequency power supply 208, which is a high-frequency power supply, is connected to an end portion of the waveguide 209. The plasma generating high-frequency power supply 208 is a power supply for generating electromagnetic waves for plasma generation. For example, microwaves with a frequency of 2.45 GHz are used as the electromagnetic waves. The microwaves generated from the plasma generating high-frequency power supply 208 propagate through the waveguide 209 and are injected to the processing chamber 201. Since the waveguide 209 includes a vertical waveguide extending in the vertical direction and a waveguide converter that also serves as a corner that bends a direction of the microwaves by 90 degrees, the microwaves are vertically incident on the processing chamber 201. The microwaves propagate vertically in the processing chamber 201 through the window portion 203. Magnetic field generating coils 210 disposed on an outer periphery of the processing chamber 201 form a magnetic field in the processing chamber 201. The microwaves oscillated from the plasma generating high-frequency power supply 208 generate a high-density plasma in the processing chamber 201 by an interaction between the magnetic fields formed by the magnetic field generating coils 210.

A sample stage 212 is disposed below the processing chamber 201 in a manner of facing the window portion 203. Aluminum or titanium is used as the material of the sample stage 212. A semiconductor substrate 211, which is a sample, is placed and held on an upper surface of the sample stage 212. Here, center axes of the waveguide 209, the processing chamber 201, the sample stage 212, and the semiconductor substrate 211 coincide with one another. An electrode for electrostatically attracting the semiconductor substrate 211 is provided inside the sample stage 212, and the semiconductor substrate 211 is electrostatically attracted to the sample stage 212 by applying a DC voltage. Further, a high-frequency voltage is applied to the sample stage 212 from a high-frequency bias power supply 213 in order to control isotropy and anisotropy of etching. A frequency of the high-frequency bias to be applied may be, for example, 400 KHz.

Each mechanism of the plasma processing apparatus 200 is controlled by a control signal 221 from a control unit 220. The control unit 220 controls each mechanism by instructing each mechanism to perform a predetermined operation using the control signal 221 according to processing conditions (anisotropic etching processing, isotropic etching processing, ALD film formation processing, and the like) executed by the plasma processing apparatus 200. The control unit 220 controls, for example, the plasma generating high-frequency power supply 208 to control ON-OFF of the electromagnetic waves for plasma generation. The control unit 220 controls the gas supply mechanism to adjust a type, a flow rate, and the like of the gas introduced into the processing chamber 201. The control unit 220 also controls the high-frequency bias power supply 213 to control an intensity of the high-frequency voltage applied to the semiconductor substrate 211 on the sample stage 212.

When anisotropic etching is performed using the plasma processing apparatus 200, the control unit 220 controls the magnetic field generating coils 210 such that plasma is generated in the lower portion 201B of the processing chamber 201 below the perforated plate 204. Since the perforated plate 204 is made of a dielectric material, the microwaves pass through the perforated plate 204 and interact with the magnetic field in the lower portion 201B of the processing chamber 201 to generate plasma. Further, a high-frequency bias is applied to the sample stage 212 on which the Si substrate 1 as the semiconductor substrate 211 is placed. Accordingly, the ions in the plasma are attracted to the Si substrate 1 without being blocked by the perforated plate 204 or the like, and etching while maintaining the verticality is possible.

When isotropic etching is performed using the plasma processing apparatus 200, the control unit 220 controls the magnetic field generating coils 210 such that a plasma generation position is located at the upper portion 201A of the processing chamber 201 above the perforated plate 204. Since ions in the plasma generated in the upper portion 201A of the processing chamber 201 are shielded by the perforated plate 204, only radicals in the plasma are supplied to the lower portion 201B of the processing chamber. Accordingly, isotropic etching using radicals is possible.

When a film is formed by the ALD method using the plasma processing apparatus 200, the following cycle process controlled by the control unit 220 may be applied. For example, when a Si₃N₄ film is to be formed by the ALD method, BTBAS or BDEAS as a raw material of Si or SiH₂Cl₂ as a gas is used. When BTBAS or BDEAS as a liquid raw material is used, the liquid raw material is vaporized and sent to a gas line as a gas. The raw material gas is sent into the processing chamber 201 together with Ar, which is a carrier gas, and is attracted on a substrate surface as a precursor of Si. Thereafter, an unnecessary precursor in the processing chamber 201 is exhausted using a purge gas such as Ar gas. Subsequently, a gas containing nitrogen, such as N₂ gas, a mixed gas of N₂ gas and H₂ gas, or NH₃ gas, is introduced into the processing chamber 201 to be converted into plasma, and is reacted with the substrate surface. Thereafter, an inert gas such as Ar is introduced into the processing chamber 201 again to purge an inside of the processing chamber 201, and an unnecessary gas in the processing chamber 201 is exhausted. According to this series of processes, in principle, a Si₃N₄ film having a film thickness of an atomic layer level is deposited on the substrate surface. By repeatedly performing this series of processes (performing a cycle process), a thin insulating film is formed by the ALD method. For example, when an Al₂O₃ film is to be formed by the ALD method, Al(CH₃)₃ is used as a precursor of Al, vaporized H₂O is used as a raw material of oxygen, and the same cycle process as that in the case of Si₃N₄ is performed to form the Al₂O₃ film.

### Embodiment 2

In Embodiment 2, a method for protecting a Si channel sidewall when forming a gate-semiconductor substrate isolation film (311 in FIG. 6B: corresponding to the gate-semiconductor substrate insulating isolation film 11 in Embodiment 1) is provided.

FIG. 6A shows the same drawing as that after removal of the Si sacrificial layer 4A shown in FIG. 1J in the gate-semiconductor substrate isolation film formation step (the steps shown in FIGS. 1A to IN) described in Embodiment 1. In the present embodiment, steps 101 to 109 in FIG. 4, that is, steps from the gate sidewall spacer vertical etching shown in FIG. 1B to the isotropic etching removal of the Si sacrificial layer 4A shown in FIG. 1J are performed continuously in the same plasma processing apparatus 200, and then the Si substrate 1 is taken out from the plasma processing apparatus 200.

Thereafter, in the step shown in FIG. 6B, a gate-substrate isolation insulating film 311 is deposited, and a surface thereof is planarized by CMP using the hard mask 307 as a stopper. The gate-substrate isolation insulating film 311 is formed using the CVD method or the like. A material of the gate-substrate isolation insulating film 311 uses, for example, SiO₂, SiON, or SiCO. By the above formation, a region between a first SiGe sacrificial layer 303 and a Si substrate 301 is filled with the gate-substrate isolation insulating film 311, and the gate-substrate isolation insulating film 311 is also deposited on sidewalls of first protective dielectric films 309 and a second protective dielectric films 310.

In the step shown in FIG. 6C, the gate-substrate isolation insulating film 311 is etched back in the vertical direction. An etching amount may be adjusted such that an upper surface of the gate-substrate isolation insulating film 311 after the etch back is located between a lower surface of the second protective dielectric film 310 and an upper surface of a lowermost first SiGe sacrificial layer 303. At the time of this etch back, since sidewalls of a stacked film including first SiGe sacrificial layers 303 and Si channels 304 are protected by the first protective dielectric films 309 and the second protective dielectric films 310, sidewalls of the Si channels 304 are not damaged by ions or radicals at the time of the etch back. Therefore, it is possible to manufacture a GAA type FET in which degradation of transistor characteristics due to etching damage is prevented.

Next, in the step shown in FIG. 6D, the second protective dielectric films 310 and the first protective dielectric films 309 are sequentially removed by isotropic etching. Etching conditions other than an etching time may be the same as those in Embodiment 1. After the etching, the second protective dielectric films 310 and the first protective dielectric films 309 may be left so as to keep on filling trenches formed between the gate-substrate isolation insulating film 311 and the first SiGe sacrificial layer 303. The etching time of each of the second protective dielectric films 310 and the first protective dielectric films 309 is adjusted such that upper surfaces of the etched second protective dielectric films 310 and the etched first protective dielectric films 309 coincide with the upper surface of the gate-substrate isolation insulating film 311. Since the remaining second protective dielectric films 310 and the first protective dielectric films 309 are present in the trenches, it is possible to prevent generation of cavities originating from the trenches in subsequent processes.

### Embodiment 3

In Embodiment 3, a method for simplifying a process of forming a gate sidewall inner spacer (12 in Embodiment 1) is provided. FIGS. 7A to 7K are cross-sectional views of processes using this method, and FIG. 8 is a flowchart of a process using this method.

FIG. 7A is a cross-sectional view in a direction perpendicular to a gate corresponding to an anisotropic etching step of the stacked film including the first SiGe sacrificial layers 3B (402B in FIG. 7A) and the Si channels 4B (403B in FIG. 7A) shown in FIG. 1C. However, unlike FIG. 1C in which etching is performed to the Si sacrificial layer 4A, etching is stopped at an upper portion of a Si sacrificial layer 403A. In the present embodiment, in FIG. 7A, it is desirable to complete the etching in a state where the Si sacrificial layer 403A is exposed after a stacked film including first SiGe sacrificial layers 402B and Si channels 403B is etched in the vertical direction. A depth at which the Si sacrificial layer 403A is etched by over etching is preferably adjusted, for example, within a range from 0 nm to about 90% of a film thickness of the Si sacrificial layer 403A. This step corresponds to step 502 of a process flow in FIG. 8, and may be performed continuously in the chamber of the same apparatus after an etching step (501 in FIG. 8) of the gate sidewall spacer 8 shown in FIG. 1B.

In FIG. 7B, the first SiGe sacrificial layers 402B are isotropically etched. The etching conditions are the same as those in Embodiment 1, and the etching is performed under selective etching conditions selective to hard masks 406, gate sidewall spacers 407, an STI insulating film (not shown), the Si channels 403B, and the Si sacrificial layer 403A. The etching time is adjusted such that the etching amount is, for example, about 1 nm to 10 nm. This step corresponds to step 503 of the process flow in FIG. 8, and may be performed continuously in the chamber of the same apparatus after an anisotropic etching step (502 in FIG. 8) of the stacked film including the first SiGe sacrificial layers 402B and the Si channels 403B shown in FIG. 7A.

In FIG. 7C, a first protective dielectric film 408 is deposited by the film formation technique using the ALD method. The first protective insulating film 408 is deposited on upper surfaces and sidewalls of the hard masks 406 and the gate sidewall spacers 407, sidewalls of the stacked film including the first SiGe sacrificial layers 402B and the Si channels 403B, an upper surface of the Si sacrificial layer 403A, and the STI insulating film (not shown). Here, the first protective dielectric film 408 is also formed in trenches formed by isotropically etching the first SiGe sacrificial layers 402B in FIG. 7B, and is also formed on upper surfaces and lower surfaces of the exposed Si channels 403B in the region. A material of the first protective dielectric film 408 is preferably an dielectric film containing nitrogen in consideration of an etching selectivity ratio between the stacked film including the first SiGe sacrificial layers 402B and the Si channels 403B and the Si sacrificial layer 403A and the peripheral STI insulating film (not shown), and is, for example, a Si₃N₄ film or a SiON film similar thereto. A film thickness of the first protective dielectric film 408 is controlled to, for example, about 2 nm to 3 nm. Film forming conditions using the ALD method may be the same as those in Embodiment 1. This step corresponds to step 504 of the process flow in FIG. 8, and may be performed continuously in the chamber of the same apparatus after an isotropic etching step (503 in FIG. 8) of the first SiGe sacrificial layers 402B shown in FIG. 7B.

In the step shown in FIG. 7D, the first protective dielectric film 408 is etched in the vertical direction. The etching is performed under selective etching conditions selective to the hard masks 406, the gate sidewall spacers 407, the Si sacrificial layer 403A, and the STI insulating film (not shown). For example, when the first protective dielectric film 408 is a Si₃N₄ film, the etching conditions may be the conditions shown in Embodiment 1. After this step, the upper surface of the Si sacrificial layer 403A is exposed. After this etching, the etching conditions are controlled such that a residual film thickness of the Si sacrificial layer 403A is, for example, 10% to 100% with respect to an initial film thickness of the Si sacrificial layer 403A. A distance in the horizontal direction between an opening region of the Si sacrificial layer 403A exposed after the etching of the first protective dielectric film 408 in this step and the first SiGe sacrificial layer 402B is wider than that in the case shown in FIG. 1E of Embodiment 1. Therefore, even when over etching is performed on the first protective dielectric film 408, unlike the case shown in FIG. 2B, a sidewall of the first SiGe sacrificial layer 402B is unlikely to be exposed. This step corresponds to step 505 of the process flow in FIG. 8, and may be performed continuously in the chamber of the same apparatus after a film forming step (504 in FIG. 8) of the first protective dielectric film 408 shown in FIG. 7C.

In the step shown in FIG. 7E, a second protective dielectric film 409 is formed on the first protective dielectric film 408 using the ALD method. The second protective dielectric film 409 is deposited on the upper surfaces and sidewalls of the hard masks 406, the gate sidewall spacers 407, and the first protective dielectric film 408, the upper surface of the Si sacrificial layer 403A, and the STI insulating film (not shown). When gaps due to trenches caused by isotropic etching of the first SiGe sacrificial layers 402B remain after the formation of the first protective dielectric film 408 shown in FIG. 7C, the second protective dielectric film 409 is formed to fill the gaps in this step. As the second protective dielectric film 409, an Al₂O₃ film, an AlON film, or the like which can be conformally deposited with good controllability even in a complicated shape having finer irregularities is used. For example, in the case of forming an Al₂O₃ film, the same conditions as those in Embodiment 1 may be used. This step corresponds to step 506 of the process flow in FIG. 8, and may be performed continuously in the chamber of the same apparatus after an anisotropic etching step (505 in FIG. 8) of the first protective dielectric film 408 shown in FIG. 7D.

In the step shown in FIG. 7F, the second protective dielectric film 409 is etched in the vertical direction. The etching is performed under selective etching conditions selective to the first protective dielectric film 408, the hard masks 406, the gate sidewall spacers 407, the Si sacrificial layer 403A, and the STI insulating film (not shown). For example, when the protective dielectric film 409 is an Al₂O₃ film, the etching conditions may be the conditions shown in Embodiment 1. After this step, the upper surface of the Si sacrificial layer 403A is exposed. After this etching, the etching conditions are controlled such that the residual film thickness of the Si sacrificial layer 403A is, for example, 10% to 100% with respect to the initial film thickness of the Si sacrificial layer 403A.

In the step shown in FIG. 7E, since the second protective dielectric film 409 is formed to fill the gaps formed on sidewalls of the first protective dielectric film 408, the distance between a sidewall of the second protective dielectric film 409 and a sidewall of the Si channel 403B can be sufficiently maintained, and corner portions of the sidewalls of the Si channels 403B are sufficiently protected in the etching of the second protective dielectric film 409 in this step, the etching of the Si sacrificial layer 403A and the second SiGe sacrificial layer 402A after this step, and the like. In the case where the second protective dielectric film 409 is not provided, when the film thickness of the first protective dielectric film 408 is reduced at the corner portions of the sidewalls of the Si channels 403B, there is a concern that the corner portions of the sidewalls of the Si channels 403B may be damaged during etching in this step and subsequent steps. This step corresponds to step 507 of the process flow in FIG. 8, and may be performed continuously in the chamber of the same apparatus after a film forming step (506 in FIG. 8) of the second protective dielectric film 409 shown in FIG. 7E.

In the step shown in FIG. 7G, the Si sacrificial layer 403A and the second SiGe sacrificial layer 402A are etched in the vertical direction. This etching is anisotropic selective etching using the hard masks 406, the gate sidewall spacers 407, and the second protective dielectric film 409 as masks, and the Si sacrificial layer 403A and the second SiGe sacrificial layer 402A are vertically etched along sidewalls of the second protective dielectric film 409. In this step, the etching is ended when the Si substrate 1 is exposed. The etching in this step may be performed under the same conditions as those used in the anisotropic etching of the pattern of the stacked film of the SiGe layers 3 and the Si layers 4 in FIG. 1C of Embodiment 1. This step corresponds to step 508 of the process flow in FIG. 8, and may be performed continuously in the chamber of the same apparatus after an anisotropic etching step (507 in FIG. 8) of the second protective dielectric film 409 shown in FIG. 7F.

In the step shown in FIG. 7H, the second SiGe sacrificial layer 402A and the Si sacrificial layer 403A are sequentially removed by isotropic etching. The etching of the second SiGe sacrificial layer 402A may be performed under the same conditions as the conditions used in FIG. 1I of Embodiment 1 using selective etching conditions selective to the second protective dielectric film 409, the first protective dielectric film 408, the hard masks 406, the gate sidewall spacers 407, the STI insulating film (not shown), the Si sacrificial layer 403A, and a Si substrate 401. The etching of the Si sacrificial layer 403A may be performed under the same conditions as the conditions used in FIG. 1J of Embodiment 1 using selective etching conditions selective to the second protective dielectric film 409, the first protective dielectric film 408, the hard masks 406, the gate sidewall spacers 407, the STI insulating film (not shown), and the second SiGe sacrificial layers 402B. This step corresponds to step 509 of the process flow in FIG. 8, and may be performed continuously in the chamber of the same apparatus after an anisotropic etching step (508 in FIG. 8) of the Si sacrificial layer 403A and the second SiGe sacrificial layer 402A shown in FIG. 7G.

In the step shown in FIG. 7I, the second protective dielectric film 409 and the first protective dielectric film 408 are sequentially removed by isotropic etching. The etching of the second protective dielectric film 409 is performed under selective etching conditions selective to the first protective dielectric film 408, the hard masks 406, the gate sidewall spacers 407, the STI insulating film (not shown), lower surfaces of the first SiGe sacrificial layers 402B, and the Si substrate 401. For example, when the second protective dielectric film 409 is an Al₂O₃ film, the etching conditions may be the conditions shown in FIG. 1K of Embodiment 1. The etching of the second protective dielectric film 408 is performed under selective etching conditions selective to the hard masks 406, the gate sidewall spacers 407, the STI insulating film (not shown), the first SiGe sacrificial layers 402B, the Si channels 403B, and the Si substrate 401. For example, when the first protective dielectric film 408 is a Si₃N₄ film, the etching conditions may be the conditions shown in FIG. 1K of Embodiment 1. By this step, sidewalls of the gate sidewall spacers 407, the first SiGe sacrificial layers 402B and the Si channels 403B are exposed. Upper surfaces and lower surfaces of the Si channels 403B in regions of the trenches formed by the isotropic etching of the first SiGe sacrificial layers 402B are also exposed at the same time. This step corresponds to step 510 of the process flowchart in FIG. 8, and may be performed continuously in the chamber of the same apparatus after an etching removal step (509 in FIG. 8) of the second SiGe sacrificial layer 402A and the Si sacrificial layer 403A shown in FIG. 7H. That is, in the process flow in FIG. 8, steps from a gate sidewall spacer vertical etching step 501 (FIG. 1B) to a first and second protective dielectric films isotropic etching removal step 510 (FIG. 7I) can be performed continuously in the chamber of the same apparatus.

Next, in the step shown in FIG. 7J, a gate-substrate isolation insulating film 410 is deposited, and a surface thereof is planarized by CMP using the hard mask 406 as a stopper. The gate-substrate isolation insulating film 410 is formed using the CVD method or the like. A material of the gate-substrate isolation insulating film 410 uses, for example, SiO₂, SiON, or SiCO. By the above formation, regions between the lower surfaces of the first SiGe sacrificial layers 402B and the Si substrate 401 are filled with the gate-substrate isolation insulating film 410, and trenches interposed between the sidewalls of the first SiGe sacrificial layers 402B and upper and lower Si channels 403B are also filled with the gate-substrate isolation insulating film 410.

In the step shown in FIG. 7K, anisotropic etching in the vertical direction is performed on the gate-substrate isolation insulating film 410. The etching of the gate-substrate isolation insulating film 410 is performed under selective etching conditions selective to the hard masks 406, the gate sidewall spacers 407, an STI insulating film (not shown), and the sidewalls of the Si channels 403B. An etching time thereof is controlled such that an upper surface of the gate-substrate isolation insulating film 410 after etching is located between a lower surface and an upper surface of a lowermost first SiGe sacrificial layer 402B. According to this step, the trenches interposed between the sidewalls of the first SiGe sacrificial layers 402B and the upper and lower Si channels 403B are filled with the interlayer insulating film 410, and a gate sidewall inner spacer can be formed simultaneously with the formation of the gate-substrate isolation insulating film 410.

As described above, in the present embodiment, the gate sidewall inner spacer can be formed simultaneously with the gate-semiconductor substrate insulating isolation film, thereby simplifying the process steps. As shown in FIG. 7D, the first SiGe sacrificial layer 402B is prevented from being exposed when the protective insulating film is etched. In the present embodiment, the Si sacrificial layer 403A and the second SiGe sacrificial layer 402A are etched in a state where sidewalls of a stacked film including the first SiGe sacrificial layers 402B and the Si channels 403B have an irregular shape, but as shown in FIG. 7F, by providing the second protective dielectric film 409, it is also possible to reduce damage to the corner portions of the sidewalls of the Si channels 403B.

### Embodiment 4

In Embodiment 4, a method for reinforcing a gate sidewall inner spacer by using a protective dielectric film is provided.

FIG. 9A shows a cross-sectional view after isotropic etching of the first SiGe sacrificial layers 402B shown in FIG. 7B using the same process as in Embodiment 3. In the present embodiment, steps from the gate sidewall spacer vertical etching shown in 501 in FIG. 8 to the first SiGe sacrificial film isotropic etching shown in 503 are performed continuously in the chamber of the same apparatus, and then a Si substrate 601 is taken out from the apparatus once.

Thereafter, in FIG. 9B, a low dielectric constant film 608 for forming the gate sidewall inner spacer is formed using the CVD method or the like. As the low dielectric constant film 608, for example, a SiCO film, a SiOCN film, a SiON film, a film similar thereto, or a stacked film thereof may be used. After this step, the Si substrate 601 is put again into the plasma processing apparatus in which the step shown in FIG. 9A is performed, and the step shown in FIG. 9C and the subsequent steps are performed.

In FIG. 9C, the low dielectric constant film 608 is subjected to isotropic etching to form a gate sidewall inner spacer. The etching may be performed under the same conditions as those in Embodiment 1, and an etching time thereof is adjusted such that sidewalls of Si channels 603B are exposed. After this etching, it is assumed that sidewalls of gate sidewall inner spacers 608 have a curved shape.

In FIG. 9D, a first protective dielectric film 609 is deposited by the film formation technique using the ALD method. The first protective dielectric film 609 is deposited on upper surfaces and sidewalls of hard masks 606 and gate sidewall spacers 607, sidewalls of the gate sidewall inner spacers 608, sidewalls of the Si channels 603B, an upper surface of a Si sacrificial layer 603A, and an STI insulating film (not shown). Film formation conditions of the first protective dielectric film 609 may be the same as the conditions shown in FIG. 1D of Embodiment 1. This step may be performed continuously in the chamber of the same apparatus after the isotropic etching of the low dielectric constant film 608 shown in FIG. 9C.

In the step shown in FIG. 9E, the first protective dielectric film 609 is etched in the vertical direction. The etching is performed under selective etching conditions selective to the hard masks 606, the gate sidewall spacers 607, the Si sacrificial layer 603A, and the STI insulating film (not shown). For example, when the first protective dielectric film 609 is a Si₃N₄ film, the etching conditions may be the conditions shown in Embodiment 1. After this step, the upper surface of the Si sacrificial layer 603A is exposed. After this etching, the etching conditions are controlled such that a residual film thickness of the Si sacrificial layer 603A is, for example, 10% to 100% with respect to an initial film thickness of the Si sacrificial layer 603A. In the step shown in FIG. 9F, a second protective dielectric film 610 is formed on the first protective dielectric film 609 using the ALD method. The second protective dielectric film 610 is deposited on the upper surfaces and the sidewalls of the hard masks 606, the gate sidewall spacers 607, and the first protective dielectric film 609, the upper surface of the Si sacrificial layer 603A, and the STI insulating film (not shown). When gaps caused by the curved shape of gate sidewall spacers 607 remain after formation of the first protective dielectric film 609 shown in FIG. 9D, the second protective dielectric film 610 is formed to fill the gaps in this step. As the second protective dielectric film 610, an Al₂O₃ film, an AlON film, or the like which can be conformally deposited with good controllability even in a complicated shape having finer irregularities is used. For example, in the case of forming an Al₂O₃ film, the same conditions as those in Embodiment 1 may be used. This step may be performed continuously in the chamber of the same apparatus after the anisotropic etching of the first protective dielectric film 609 shown in FIG. 9E.

In the step shown in FIG. 9G, the second protective dielectric film 610 is etched in the vertical direction. The etching is performed under selective etching conditions selective to the first protective dielectric film 609, the hard masks 606, the gate sidewall spacers 607, the Si sacrificial layer 603A, and the STI insulating film (not shown). For example, when the protective dielectric film 610 is an Al₂O₃ film, the etching conditions may be the conditions shown in Embodiment 1. After this step, the upper surface of the Si sacrificial layer 603A is exposed. After this etching, the etching conditions are controlled such that the residual film thickness of the Si sacrificial layer 603A is, for example, 10% to 100% with respect to the initial film thickness of the Si sacrificial layer 603A. This step may be performed continuously in the chamber of the same apparatus after the formation of the second protective dielectric film 610 shown in FIG. 9F.

In the step shown in FIG. 9H, the Si sacrificial layer 603A and the second SiGe sacrificial layer 602A are etched in the vertical direction. This etching is anisotropic selective etching using the hard masks 606, the gate sidewall spacers 607, and the second protective dielectric film 610 as masks, and the Si sacrificial layer 603A and the second SiGe sacrificial layer 602A are vertically etched along sidewalls of the second protective dielectric film 610. In this step, the etching is ended when the Si substrate 601 is exposed. The etching in this step may be performed under the same conditions as those used in the anisotropic etching of the pattern of the stacked film of the SiGe layers 3 and the Si layers 4 in FIG. 1C of Embodiment 1. This step may be performed continuously in the chamber of the same apparatus after the anisotropic etching of the second protective dielectric film 610 shown in FIG. 9G.

In the step shown: in FIG. 9I, the second SiGe sacrificial layer 602A and the Si sacrificial layer 603A are sequentially removed by isotropic etching. The etching of the second SiGe sacrificial layer 602A may be performed under the same conditions as the conditions used in FIG. 1I of Embodiment 1 using the selective etching conditions selective to the second protective dielectric film 609, the first protective dielectric film 608, the hard masks 606, the gate sidewall spacers 607, the STI insulating film (not shown), the Si sacrificial layer 603A, and the Si substrate 601. The etching of the Si sacrificial layer 603A may be performed under the same conditions as the conditions used in FIG. 1J of Embodiment 1 using selective etching conditions for the second protective dielectric film 610, the first protective dielectric film 609, the hard masks 606, the gate sidewall spacers 607, the gate sidewall inner spacers 608, the STI insulating film (not shown), and the first SiGe sacrificial layers 602B. This step may be performed continuously in the chamber of the same apparatus after anisotropic etching of the Si sacrificial layer 603A and the second SiGe sacrificial layer 602A shown in FIG. 9H.

In the step shown in FIG. 9J, isotropic etching of the second protective dielectric film 610 and the first protective dielectric film 609 is sequentially performed. The etching of the second protective dielectric film 610 is performed under selective etching conditions selective to the first protective dielectric film 609, the hard masks 606, the gate sidewall spacers 607, the STI insulating film (not shown), lower surfaces of the first SiGe sacrificial layers 602B, and the Si substrate 601. For example, when the second protective dielectric film 610 is an Al₂O₃ film, the etching conditions may be the conditions shown in FIG. 1K of Embodiment 1. Here, the isotropic etching of the second protective dielectric film 610 is performed by adjusting an etching time such that sidewalls of the first protective dielectric film 609 are exposed after the etching, and the etching time is preferably adjusted such that the second protective dielectric film 610 buried in the gaps caused by the curved shape of the sidewalls of the gate sidewall inner spacers 608 remains. The etching of the first protective dielectric film 609 is performed under selective etching conditions selective to the second protective dielectric film 610, the hard masks 606, the gate sidewall spacers 607, the STI insulating film (not shown), the gate sidewall inner spacers 608, the lower surfaces of the first SiGe sacrificial layer 602B, the Si channels 603B, and the Si substrate 601. For example, when the first protective dielectric film 609 is a Si₃N₄ film, the etching conditions may be the conditions shown in FIG. 1K of Embodiment 1. In the etching in this step, the etching time is adjusted such that sidewalls of the gate sidewall spacers 607, the gate sidewall inner spacers 608, and the Si channels 603B are exposed, and the etching time is preferably adjusted such that the second protective dielectric film 610 and the first protective dielectric film 609 that are embedded in the gaps caused by the curved shape of the sidewalls of the gate sidewall inner spacers 608 remain. This step may be performed continuously in the chamber of the same apparatus after an etching removal step of the second SiGe sacrificial layer 602A and the Si sacrificial layer 603A shown in FIG. 9I. That is, steps from the isotropic etching of the low dielectric constant film for forming the gate sidewall inner spacers 608 shown in FIG. 9C to the isotropic etching of the second protective dielectric film 610 and the first protective dielectric film 609 shown in FIG. 9J can be performed continuously in the chamber of the same apparatus.

Thereafter, the GAA type FET is completed by performing the processes shown in FIG. 1L and subsequent drawings in Embodiment 1. In the GAA type FET produced according to the present embodiment, since recesses of the gate sidewall inner spacers 608 are filled with the second protective dielectric film 610 and the first protective dielectric film 609, it is possible to avoid current leakage or the like caused by a pinhole-like defect generated due to a recess shape of the gate sidewall inner spacers 608.

### REFERENCE SIGNS LIST

1, 301, 401, 601: silicon substrate

2, 302: shallow trench isolation (STI) insulating film

3: single crystal silicon germanium layer

3A, 402A, 602A: second silicon germanium sacrificial layer

3B, 303, 402B, 602B: first silicon germanium sacrificial layer

4: single crystal silicon layer

4A, 403A, 603A: silicon sacrificial layer

4B, 304, 403B, 603B: silicon channel layer

5, 305, 404, 604: dummy gate insulating film

6, 306, 405, 605: polysilicon dummy gate

7, 307, 406, 606: hard mask

8, 308, 407, 607: gate sidewall spacer

9, 309, 408, 609: first protective dielectric film

10, 310, 409, 610: second protective dielectric film

11, 311, 410: gate-substrate isolation insulating film

12, 608: gate sidewall inner spacer

13: gate insulating film

14: gate metal

15: source/drain

16: second interlayer insulating film

17: contact barrier metal

18: contact metal

101, 501: gate sidewall spacer vertical etching step

102, 502: silicon/silicon germanium stacked film vertical etching step

503: first SiGe sacrificial film isotropic etching

103, 504: first protective dielectric film deposition step

104, 505: first protective dielectric film vertical etching step

105, 506: second protective dielectric film deposition step

106, 507: second protective dielectric film vertical etching step

107: second silicon germanium sacrificial film anisotropic etching step

108: second silicon germanium sacrificial film isotropic etching step

109: silicon sacrificial film isotropic etching step

508: silicon sacrificial film/second silicon germanium sacrificial film anisotropic etching

509: silicon sacrificial film/second silicon germanium sacrificial film isotropic etching

110, 510: first/second protective dielectric film isotropic etching step

201: processing chamber (chamber)

201A: processing chamber upper region

201B: processing chamber lower region

202: vacuum exhaust port

203: window portion

204: perforated plate

205: gas source

206: gas supply device

207: gas introduction port

208: plasma generating high-frequency power supply

209: waveguide

210: magnetic field generating coil

211: semiconductor substrate

212: sample stage

213: high-frequency bias power supply

220: control unit

221: control signal

t1: film thickness of first protective dielectric film in horizontal direction

t2: film thickness of first protective dielectric film in vertical direction at bottom of trench

t3: film thickness of second protective dielectric film in horizontal direction

t4: film thickness of second protective dielectric film in horizontal direction at bottom of trench

t5: film thickness of second protective dielectric film in vertical direction at bottom of trench

θ1: angle formed between sidewall of silicon/silicon germanium stacked film and upper surface of second silicon germanium sacrificial layer 3A

θ2: angle formed between sidewall of silicon/silicon germanium stacked film and lower surface of first protective dielectric film after etching

a1: source gas flow path at the time of forming second protective dielectric film

a2: ion irradiation path at the time of etching second protective dielectric film

1. A method for manufacturing a semiconductor device that includes a stacked channel in which thin or sheet-shaped channels are stacked in a direction perpendicular to a substrate in a gate formation region, and that insulation-isolates a gate and a semiconductor substrate from each other by an insulating film,
the semiconductor device having a structure in which a stacked film is provided in which a plurality of first semiconductor layers and a plurality of second semiconductor layers are alternately stacked on the semiconductor substrate, the gate and a gate sidewall spacer film are further formed on the stacked film, a part of the stacked film is removed by etching along the gate sidewall spacer film, and a part or all of a lowermost first semiconductor layer or a part or all of a lowermost second semiconductor layer formed on the lowermost first semiconductor layer are left without being etched, the method comprising:
a first step of depositing a protective dielectric film on a sidewall of the stacked film including the first semiconductor layers and the second semiconductor layers that are formed by the etching;
a second step of subjecting the protective dielectric film to anisotropic etching in a vertical direction to expose a surface of the lowermost first semiconductor layer or the lowermost second semiconductor layer;
a third step of repeating the first step and the second step a plurality of times using a material of the insulating film different from that of the protective dielectric film, and forming, on the sidewall, a stacked film of protective dielectric films including the protective dielectric film and a plurality of protective dielectric films different from the protective dielectric film; and
a fourth step of removing the lowermost first semiconductor layer or the lowermost first semiconductor layer and the lowermost second semiconductor layer by etching.

2. The method for manufacturing a semiconductor device according to claim 1, wherein
the first step to the fourth step are performed continuously in the same plasma processing apparatus.

3. The method for manufacturing a semiconductor device according to claim 1, wherein
the semiconductor substrate is silicon, the first semiconductor layers are silicon germanium, and the second semiconductor layers are silicon.

4. The method for manufacturing a semiconductor device according to claim 1, wherein
among the stacked film of the protective dielectric films, a film that is in contact with the sidewall of the stacked film including the first semiconductor layers and the second semiconductor layers is formed of a film containing a silicon element and a nitrogen element, and a film that is located on an upper layer side of the stacked film of the protective dielectric films is formed of a film containing an aluminum element and an oxygen element.

5. The method for manufacturing a semiconductor device according to claim 1, wherein
after the second step, sidewalls of the second and subsequent first semiconductor layers stacked on the lowermost first semiconductor layer are exposed, and the sidewalls are covered with the stacked film of the protective dielectric films formed in the third step.

6. The method for manufacturing a semiconductor device according to claim 1, wherein
vertical etching of the gate sidewall spacer film in order to form the gate sidewall spacer film, a step of removing a part of the stacked film including the first semiconductor layers and the second semiconductor layers by vertical etching, the first step to the fourth step, and a step of removing the stacked film of the protective dielectric films by isotropic etching are performed continuously in the same plasma processing apparatus.

7. The method for manufacturing a semiconductor device according to claim 1, wherein
vertical etching of the gate sidewall spacer film in order to form the gate sidewall spacer film, a step of removing a part of the stacked film including the first semiconductor layers and the second semiconductor layers by vertical etching, and the first step to the fourth step are performed continuously in the same plasma processing apparatus, and in a subsequent step, a first insulating film for insulation-isolating the gate and the semiconductor substrate is deposited and subjected to vertical etching.

8. The method for manufacturing a semiconductor device according to claim 1, wherein
after removing a part of the stacked film including the first semiconductor layers and the second semiconductor layers by vertical etching, sidewalls of the first semiconductor layers other than the lowermost layer are subjected to isotropic etching, and thereafter, the first step to the fourth step and a step of removing the stacked film of the protective dielectric films by isotropic etching are performed continuously in the same plasma processing apparatus.

9. The method for manufacturing a semiconductor device according to claim 1, further comprising:
a step of, after removing a part of the stacked film including the first semiconductor layers and the second semiconductor layers by the vertical etching, subjecting sidewalls of the first semiconductor layers other than the lowermost layer to isotropic etching, and depositing a low dielectric constant film in a trench formed by the isotropic etching, wherein
a step of removing a part of the low dielectric constant film by isotropic etching to form a gate sidewall inner spacer formed of the low dielectric constant film in the trench, the first step to the fourth step, and a step of removing a part of the stacked film of the protective dielectric films by isotropic etching are performed continuously in the same plasma processing apparatus, and after the continuous steps, a gap formed in a sidewall of the gate sidewall inner spacer is filled with the stacked film of the protective dielectric films.

10. A plasma processing method for performing plasma processing on a structure in which a stacked film is provided in which a plurality of first semiconductor layers and a plurality of second semiconductor layers are alternately stacked on a semiconductor substrate, a gate and a gate sidewall spacer film are further formed on the stacked film, a part of the stacked film is removed by etching along the gate sidewall spacer film, and a part or all of a lowermost first semiconductor layer or a part or all of a lowermost second semiconductor layer formed on the lowermost first semiconductor layer are left without being etched, the plasma processing method comprising continuously performing:
a first step of depositing a protective dielectric film on a sidewall of the stacked film including the first semiconductor layers and the second semiconductor layers that are formed by the etching;
a second step of subjecting anisotropic etching to the protective dielectric film in a vertical direction to expose a surface of the lowermost first semiconductor layer or the lowermost second semiconductor layer;
a third step of repeating the first step and the second step a plurality of times using a material of an insulating film different from that of the protective dielectric film, and forming, on the sidewall, a stacked film of protective dielectric films; and
a fourth step of removing the lowermost first semiconductor layer or the lowermost first semiconductor layer and the lowermost second semiconductor layer by isotropic etching.

11. The plasma processing method according to claim 10, wherein
vertical etching of the gate sidewall spacer film in order to form the gate sidewall spacer film, a step of removing a part of the stacked film including the first semiconductor layers and the second semiconductor layers by the vertical etching, the first step to the fourth step, and a step of removing the stacked film of the protective dielectric films by the isotropic etching are performed continuously in one plasma processing apparatus.

12. The plasma processing method according to claim 10, wherein
vertical etching of the gate sidewall spacer film in order to form the gate sidewall spacer film, a step of removing a part of the stacked film including the first semiconductor layers and the second semiconductor layers by vertical etching, and the first step to the fourth step are performed continuously in one plasma processing apparatus.

13. The plasma processing method according to claim 10, wherein
after removing a part of the stacked film including the first semiconductor layers and the second semiconductor layers by the vertical etching, sidewalls of the first semiconductor layers other than the lowermost first semiconductor layer are subjected to isotropic etching, and thereafter, the first step to the fourth step and a step of removing the stacked film of the protective dielectric film by the isotropic etching are performed continuously in one plasma processing apparatus.

14. The plasma processing method according to claim 10, further comprising:
a step of, after removing a part of the stacked film including the first semiconductor layers and the second semiconductor layers by vertical etching, subjecting, sidewalls of the first semiconductor layers other than the lowermost first semiconductor layer to isotropic etching, and depositing a low dielectric constant film in a trench formed by the isotropic etching, wherein
a step of removing a part of the low dielectric constant film by isotropic etching to form a gate sidewall inner spacer formed of the low dielectric constant film in the trench, the first step to the fourth step, and a step of removing a part of the stacked film of the protective dielectric films by isotropic etching are performed continuously in one plasma processing apparatus.

15. The plasma processing method according to claim 10, wherein
in the first step and the third step, the protective dielectric film is deposited by an ALD method.
